(19) United States
(12) Patent Application Publication
(10) Pub. No.: US 2012/0001179 A1
(43) Pub. Date: Jan. 5, 2012

(54) SEMICONDUCTOR DEVICE

(75) Inventors: Shunpei YAMAZAKI, Setagaya (JP); Masahiro TAKAHASHI, Atsugi (JP); Takuya HIROHASHI, Atsugi (JP); Katsuaki TOCHIBAYASHI, Tochigi (JP); Yasutaka NAKAZAWA, Tochigi (JP); Masatoshi YOKOYAMA, Tochigi (JP)

(73) Assignee: SEMICONDUCTOR ENERGY LABORATORY CO., LTD., Kanagawa-ken (JP)

(21) Appl. No.: 13/166,073

(22) Filed: Jun. 22, 2011

(30) Foreign Application Priority Data
Jul. 2, 2010 (JP) 2010-152179
Apr. 28, 2011 (JP) 2011-100534

(51) Int. Cl. H01L 29/786

(52) U.S. Cl. 257/57; 257/E29.273

(57) ABSTRACT

It is an object to provide a semiconductor device including an oxide semiconductor, which has stable electric characteristics and high reliability. A semiconductor device having a stacked-layer structure of a gate insulating layer; a first gate electrode in contact with one surface of the gate insulating layer; an oxide semiconductor layer in contact with the other surface of the gate insulating layer and overlapping with the first gate electrode; and a source electrode, a drain electrode, and an oxide insulating layer which are in contact with the oxide semiconductor layer is provided, in which the nitrogen concentration of the oxide semiconductor layer is 2×10¹⁹ atoms/cm³ or lower and the source electrode and the drain electrode include one or more of tungsten, platinum, and molybdenum.

### BACKGROUND OF THE INVENTION

1. Field of the Invention

The present invention relates to a semiconductor device including an oxide semiconductor. The present invention also relates to a manufacturing method of the semiconductor device. Note that semiconductor devices herein refer to general elements and devices which function by utilizing semiconductor characteristics.

2. Description of the Related Art

A technique by which transistors are formed using semiconductor thin films formed over a substrate having an insulating surface has been attracting attention. The transistor is applied to a wide range of electronic devices such as an integrated circuit (IC) or an image display device (display device). A silicon-based semiconductor material is widely known as a material for a semiconductor thin film applicable to a transistor. As another material, an oxide semiconductor has been attracting attention.

For example, a transistor whose active layer includes an amorphous oxide containing indium (In), gallium (Ga), and zinc (Zn) and having an electron carrier concentration of lower than 10¹⁸/cm³ is disclosed (see Patent Document 1).

### REFERENCE

### Patent Document

[Patent Document 1] Japanese Published Patent Application No. 2006-165528

### SUMMARY OF THE INVENTION

However, the electric conductivity of an oxide semiconductor might change when deviation from the stoichiometric composition due to deficiency of oxygen or the like occurs, or hydrogen or water forming an electron donor enters the oxide semiconductor during a manufacturing process of a device. Such a phenomenon becomes a factor of variation in the electric characteristics of a semiconductor device, such as a transistor, including the oxide semiconductor.

In view of the above problem, an object is to provide a semiconductor device including an oxide semiconductor, which has stable electric characteristics and high reliability.

In order to solve the above problem, the present inventors focused on nitrogen in an oxide semiconductor layer. Nitrogen tends to be bonded to a metal included in the oxide semiconductor, and inhibits bonding between oxygen and the metal in the oxide semiconductor layer. Accordingly, it is preferable that the nitrogen concentration in the oxide semiconductor layer be 2×10¹⁹ atoms/cm³ or lower. When the nitrogen concentration in the oxide semiconductor layer is set low, the oxygen concentration in the oxide semiconductor layer can be sufficiently high.

In addition, a heat-resistant metal which is unlikely to be oxidized is used for a source electrode and a drain electrode which are in contact with the oxide semiconductor layer. For example, a layer containing one or more of tungsten, platinum, and molybdenum may be used as the source electrode and the drain electrode. Since the above metals are unlikely to react with oxygen, the source electrode and the drain electrode can be prevented from taking oxygen away from the oxide semiconductor layer.

As described above, the nitrogen concentration in the oxide semiconductor layer is set low and a heat-resistant metal which is unlikely to be oxidized is used for the source electrode and the drain electrode, so that bonding between oxygen and a metal in the oxide semiconductor layer can be prevented from being inhibited. Thus, electric characteristics and reliability of a transistor including the oxide semiconductor can be improved. For example, variation in transistor characteristics due to light deterioration can be reduced.

Specifically, one embodiment of the present invention is a semiconductor device having a stacked structure of a gate insulating layer; a first gate electrode in contact with one surface of the gate insulating layer; an oxide semiconductor layer in contact with the other surface of the gate insulating layer and overlapping with the first gate electrode; and a source electrode, a drain electrode, and an oxide insulating layer which are in contact with the oxide semiconductor layer. The nitrogen concentration of the oxide semiconductor layer is 2×10¹⁹ atoms/cm³ or lower. The source electrode and the drain electrode include at least one of tungsten, platinum, and molybdenum.

Further, a buffer layer may be formed in order to reduce the connection resistance between the oxide semiconductor layer and the source or drain electrode. The nitrogen concentration of the buffer layer is 2×10¹⁹ atoms/cm³ or lower. When the nitrogen concentration of a layer in contact with the oxide semiconductor layer is set low, the oxygen concentration in the oxide semiconductor layer can be sufficiently high, so that electric characteristics and reliability of the oxide semiconductor can be improved.

Therefore, another embodiment of the present invention is a semiconductor device having a stacked structure of a gate insulating layer; a first gate electrode in contact with one surface of the gate insulating layer; an oxide semiconductor layer in contact with the other surface of the gate insulating layer and overlapping with the first gate electrode; a buffer layer and an oxide insulating layer which are in contact with the oxide semiconductor layer; and a source electrode and a drain electrode which are electrically connected to the oxide semiconductor layer with the buffer layer interposed therebetween. The nitrogen concentration of the oxide semiconductor layer is 2×10¹⁹ atoms/cm³ or lower. The nitrogen concentration of the buffer layer is 2×10¹⁹ atoms/cm³ or lower. The source electrode and the drain electrode include at least one of tungsten, platinum, and molybdenum.

Further, an insulating layer containing oxygen, preferably an insulating layer including a region containing oxygen with a higher proportion than that in the stoichiometric composition is used as an insulating layer in contact with the oxide semiconductor layer, whereby oxygen can be supplied to the oxide semiconductor layer. In particular, a metal oxide layer is used as the layer in contact with the oxide semiconductor layer, so that impurities such as hydrogen or water are prevented from entering the oxide semiconductor layer.

In the above semiconductor device, the gate insulating layer preferably includes at least one of gallium oxide, aluminum oxide, gallium aluminum oxide, and aluminum gallium oxide.

In the above semiconductor device, the oxide insulating layer preferably includes at least one of gallium oxide, aluminum oxide, gallium aluminum oxide, and aluminum gallium oxide.

In the above semiconductor device, the thickness of the oxide semiconductor layer is preferably greater than or equal to 3 nm and less than or equal to 30 nm.

The above semiconductor device preferably includes a second gate electrode provided in a region overlapping with the oxide semiconductor layer and the first gate electrode with the oxide insulating layer interposed therebetween.

In the above semiconductor device, the nitrogen concentration of the source electrode and the drain electrode is preferably 2×10¹⁹ atoms/cm³ or lower.

Note that the electric conductivity of an oxide semiconductor changes when deviation from the stoichiometric composition due to deficiency of oxygen or the like occurs, or hydrogen or water forming an electron donor enters the oxide semiconductor during a thin film formation process. Such a phenomenon is a factor of variation in the electric characteristics of a semiconductor device including the oxide semiconductor. Thus, an impurity such as hydrogen, water, a hydroxyl group, or a hydride (also referred to as a hydrogen compound) is intentionally removed from the oxide semiconductor. In addition, oxygen which is a main component of the oxide semiconductor and may be reduced through the step of removing an impurity is supplied from the insulating layer in contact with the oxide semiconductor layer. As a result, the oxide semiconductor layer is highly purified and becomes an electrically i-type (intrinsic) oxide semiconductor.

Oxygen is diffused from the insulating layer into the oxide semiconductor layer so as to be reacted with hydrogen which is one of factors making a semiconductor device unstable, whereby hydrogen inside or at the interface of the oxide semiconductor layer can be fixed (made to be immovable ions). That is, instability can be sufficiently decreased and reliability can be improved. In addition, variation in the threshold voltages Vth or shift in the threshold voltage (ΔVth), which is due to oxygen vacancy inside or at the interface of the oxide semiconductor layer, can be reduced.

The electric characteristics of a transistor including a highly-purified oxide semiconductor layer, such as the threshold voltage and on-state current, have almost no temperature dependence. Further, transistor characteristics hardly change due to light deterioration.

According to one embodiment of the present invention, a semiconductor device including an oxide semiconductor, having favorable electric characteristics and high reliability can be provided.

### BRIEF DESCRIPTION OF THE DRAWINGS

FIGS. 1A and 1B illustrate a structural example of a transistor according to one embodiment of the present invention.

FIGS. 2A to 2D illustrate a method for manufacturing a transistor according to one embodiment of the present invention.

FIGS. 3A and 3B each illustrate a structural example of a transistor according to one embodiment of the present invention.

FIG. 4 illustrates a structural example of a transistor according to one embodiment of the present invention.

FIGS. 5A to 5C each illustrate one embodiment of a semiconductor device.

FIGS. 6A and 6B illustrate one embodiment of a semiconductor device.

FIG. 7 illustrates one embodiment of a semiconductor device.

FIG. 8 illustrates one embodiment of a semiconductor device.

FIGS. 9A to 9F illustrate electronic devices.

FIGS. 10A and 10B show observation results of Example 1.

FIG. 11 shows results of a light bias test in Example 2.

FIGS. 12A to 12C are diagrams according to Example 3.

FIGS. 13A and 13B are SIMS analysis depth profiles of Example 4.

### DETAILED DESCRIPTION OF THE INVENTION

Embodiments will be described in detail with reference to drawings. Note that the invention is not limited to the following description, and it will be easily understood by those skilled in the art that various changes and modifications can be made without departing from the spirit and scope of the invention. Therefore, the invention should not be construed as being limited to the description in the following embodiments. Note that in the structures of the invention described below, the same portions or portions having similar functions are denoted by the same reference numerals in different drawings, and description of such portions is not repeated.

### Embodiment 1

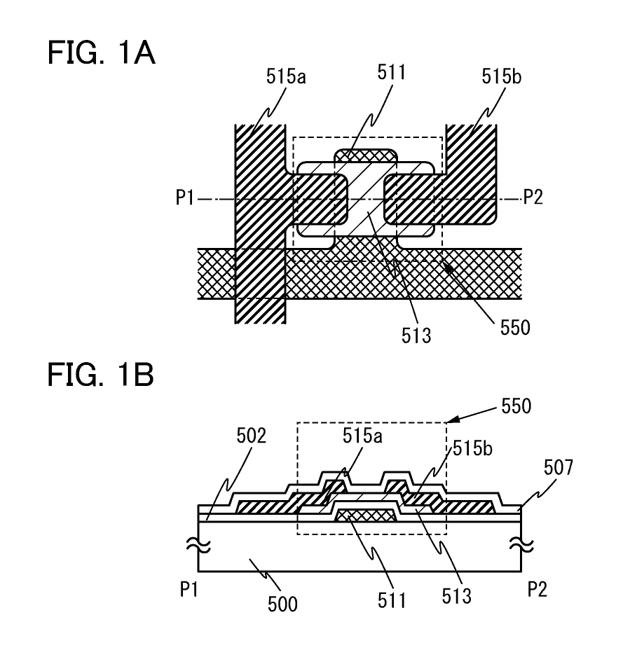

In this embodiment, a structure and a manufacturing method of a semiconductor device according to one embodiment of the present invention will be described with reference to FIGS. 1A and 1B, FIGS. 2A to 2D, FIGS. 3A and 3B, and FIG. 4.

FIGS. 1A and 1B illustrate a transistor 550 as an example of a semiconductor device. FIG. 1A is a top view of the transistor 550 and FIG. 1B is a cross-sectional view of the transistor 550. FIG. 1B illustrates a cross section along line P1-P2 in FIG. 1A.

In the transistor 550, a first gate electrode 511 and a gate insulating layer 502 which covers the first gate electrode 511 are provided over a substrate 500 having an insulating surface. An oxide semiconductor layer 513 which overlaps with the first gate electrode 511 is provided over the gate insulating layer 502. In addition, a first electrode 515a and a second electrode 515b which function as a source and a drain electrode are provided in contact with the oxide semiconductor layer 513 so as to each have an end portion overlapping with the first gate electrode 511. Further, an oxide insulating layer 507 which overlaps with the oxide semiconductor layer 513 and is in contact with part of the oxide semiconductor layer 513 is provided.

The oxide semiconductor layer 513 is preferably a highly purified oxide semiconductor layer formed by sufficiently removing an impurity such as hydrogen or water or sufficiently supplying oxygen. Specifically, the hydrogen concentration of the oxide semiconductor layer 513 is lower than or equal to 5×10¹⁹ atoms/cm³, preferably lower than or equal to 5×10¹⁸ atoms/cm³, further preferably lower than or equal to 5×10¹⁷ atoms/cm³, for example. Note that the above hydrogen concentration of the oxide semiconductor layer 513 is measured by SIMS (secondary ion mass spectroscopy). In the oxide semiconductor layer 513 which is highly purified by sufficiently reducing the hydrogen concentration therein and in which defect levels in an energy gap due to oxygen deficiency are reduced by supplying a sufficient amount of oxygen, the carrier concentration is lower than 1×10¹²/cm³, preferably lower than 1×10¹¹/cm³, further preferably lower than 1.45×10¹⁰/cm³. For example, the off-state current (here, current per micrometer (μm) of channel width) at room temperature (25° C.) is lower than or equal to 100 zA (1 zA (zeptoampere) is 1×10⁻²¹ A), preferably lower than or equal to 10 zA. In this manner, by using an i-type oxide semiconductor, a transistor having favorable electric characteristics can be obtained.

In addition, the nitrogen concentration of the oxide semiconductor layer 513 is 2×10¹⁹ atoms/cm³ or lower. In particular, the nitrogen concentration is preferably 5×10¹⁸ atoms/cm³ or lower. Nitrogen tends to be bonded to a metal included in the oxide semiconductor, and inhibits bonding between oxygen and the metal in the oxide semiconductor layer. When the nitrogen concentration in the oxide semiconductor layer is set low, the oxygen concentration in the oxide semiconductor layer can be sufficiently high, so that electric characteristics and reliability of the oxide semiconductor can be improved.

Here, the case where an In—Ga—Zn—O-based oxide semiconductor (an oxide semiconductor including indium (In), gallium (Ga), and zinc (Zn)) is used for the oxide semiconductor layer 513 will be described as an example. When the oxide semiconductor layer 513 contains much nitrogen, the nitrogen is bonded to In or Ga, so that indium nitride or gallium nitride is generated, respectively. In the oxide semiconductor layer 513, bonding between nitrogen and In or between nitrogen and Ga inhibits bonding between oxygen and In or between oxygen and Ga. As the nitrogen concentration in the oxide semiconductor layer 513 becomes high, the carrier mobility of the oxide semiconductor layer 513 becomes low. Accordingly, it is preferable that the nitrogen concentration in the oxide semiconductor layer 513 be sufficiently low.

It is preferable to form each of the gate insulating layer 502 and the oxide insulating layer 507 using an insulating film containing oxygen. It is further preferable that the gate insulating layer 502 and the oxide insulating layer 507 each include a region containing oxygen with a higher proportion than that in the stoichiometric composition (also referred to as an oxygen excess region). When the gate insulating layer 502 and the oxide insulating layer 507 which are in contact with the oxide semiconductor layer 513 each include an oxygen excess region, oxygen can be prevented from transferring from the oxide semiconductor layer 513 to the gate insulating layer 502 or the oxide insulating layer 507. In addition, oxygen can be supplied from the gate insulating layer 502 or the oxide insulating layer 507 to the oxide semiconductor layer 513. Thus, the oxide semiconductor layer 513 interposed between the gate insulating layer 502 and the oxide insulating layer 507 can contain a sufficient amount of oxygen.

In particular, the gate insulating layer 502 and the oxide insulating layer 507 are preferably formed using a material containing a Group 13 element and oxygen. As the material containing a Group 13 element and oxygen, for example, one or more of the following metal oxides can be used: gallium oxide, aluminum oxide, aluminum gallium oxide, and gallium aluminum oxide. Here, aluminum gallium oxide refers to a substance that includes aluminum (Al) at a content (atomic %) higher than that of gallium (Ga), and gallium aluminum oxide refers to a substance that includes Ga at a content (atomic %) higher than or equal to that of Al. Each of the gate insulating layer 502 and the oxide insulating layer 507 may be formed with a single-layer structure or a stacked-layer structure using any of the above materials. Since water hardly penetrates aluminum oxide, it is preferable to use a material such as aluminum oxide, aluminum gallium oxide, or gallium aluminum oxide for prevention of entry of water to the oxide semiconductor film.

As described above, it is preferable that the gate insulating layer 502 and the oxide insulating layer 507 each include a region containing oxygen with a higher proportion than that in the stoichiometric composition. Oxygen is supplied to the oxide semiconductor layer 513 or the insulating film in contact with the oxide semiconductor layer 513, so that oxygen defects in the oxide semiconductor layer 513 or at an interface between the oxide semiconductor layer 513 and the insulating film can be suppressed. For example, in the case of using a gallium oxide film as the gate insulating layer 502, a preferable composition is Ga₂Oₓ (x=3+α, 0<α<1). Here, x may be more than or equal to 3.3 and less than or equal to 3.4, for example. In the case of using an aluminum oxide film as the gate insulating layer 502, a preferable composition is Al₂Oₓ (x=3+α, 0<α<1). Alternatively, in the case of using an aluminum gallium oxide film as the gate insulating layer 502, a preferable composition is GaₓAl₂₋ₓO_{3+α} (0<x<1, 0<α<1). Further alternatively, in the case of using a gallium aluminum oxide film as the gate insulating layer 502, a preferable composition is GaₓAl₂₋ₓO_{3+α} (1<x≦2, 0<α<1).

In the case where an oxide semiconductor film without oxygen vacancies is used, the amount of oxygen contained in each of the gate insulating layer and the oxide insulating layer may be equal to that in the stoichiometric composition. However, in order to obtain reliability of the transistor, such as suppression of shift in the threshold voltage, a larger amount of oxygen is preferably contained in the gate insulating layer and the oxide insulating layer so that the proportion of oxygen can be higher than that in the stoichiometric composition; otherwise the oxide semiconductor film may have oxygen vacancies.

The first electrode 515a and the second electrode 515b each include a heat-resistant metal which is unlikely to react with oxygen, and include, for example, one or more of molybdenum (Mo), tungsten (W), and platinum (Pt). Alternatively, gold (Au) or chromium (Cr) may be used. The above metals are unlikely to be oxidized and therefore can prevent the first electrode 515a and the second electrode 515b from taking oxygen away from the oxide semiconductor layer 513. In addition, it is preferable that the nitrogen concentration of the first electrode 515a and the second electrode 515b be 2×10¹⁹ atoms/cm³ or lower.

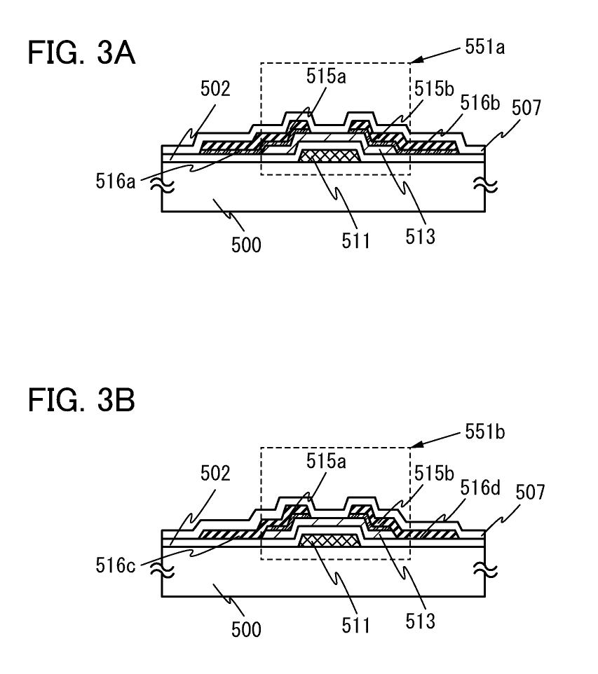

FIGS. 3A and 3B illustrate cross-sectional views of transistors 551a and 551b, respectively, each of which has a structure different from that of the transistor 550.

In each of the transistors 551a and 551b, the first gate electrode 511 and the gate insulating layer 502 which covers the first gate electrode 511 are provided over the substrate 500 having an insulating surface. The oxide semiconductor layer 513 which overlaps with the first gate electrode 511 is provided over the gate insulating layer 502. In addition, buffer layers 516a and 516b (or 516c and 516d) which are in contact with the oxide semiconductor layer 513, and the first electrode 515a and the second electrode 515b which serve as a source electrode and a drain electrode and have end portions overlapping with the first gate electrode 511 are provided. Further, the oxide insulating layer 507 which overlaps with the oxide semiconductor layer 513 and is in contact with part of the oxide semiconductor layer 513 is provided.

The buffer layer has an effect of reducing the connection resistance between the oxide semiconductor layer 513 and the first electrode 515a or the second electrode 515b. The nitrogen concentration of the buffer layer is 2×10¹⁹ atoms/cm³ or lower. In particular, the nitrogen concentration is preferably 5×10¹⁸ atoms/cm³ or lower. Nitrogen is easily bonded to a metal included in the oxide semiconductor. Since the buffer layer is in contact with the oxide semiconductor layer, nitrogen may enter the oxide semiconductor layer from the buffer layer. The nitrogen which has entered the oxide semiconductor layer prevents bonding between oxygen and the metal.

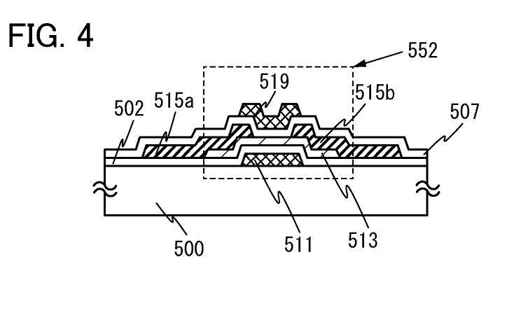

FIG. 4 is a cross-sectional view of a transistor 552 having a structure different from those of the transistors described above.

In the transistor 552, the first gate electrode 511 and the gate insulating layer 502 which covers the first gate electrode 511 are provided over the substrate 500 having an insulating surface. The oxide semiconductor layer 513 which overlaps with the first gate electrode 511 is provided over the gate insulating layer 502. In addition, the first electrode 515a and the second electrode 515b which function as a source and a drain electrode are provided in contact with the oxide semiconductor layer 513 so as to each have an end portion overlapping with the first gate electrode 511. Further, the oxide insulating layer 507 which overlaps with the oxide semiconductor layer 513 and is in contact with part of the oxide semiconductor layer 513 is provided. A second gate electrode 519 which overlaps with the first gate electrode 511 and the oxide semiconductor layer 513 is provided over the oxide insulating layer 507.

The second gate electrode 519 is provided to overlap with a channel formation region of the oxide semiconductor layer 513, which enables a reduction of the amount of shift in threshold voltage of the transistor between before and after a bias-temperature stress test (a BT test) by which reliability of the transistor is examined. Note that the potential of the second gate electrode 519 may be the same as or different from that of the first gate electrode 511. Alternatively, the potential of the second gate electrode 519 may be GND, 0 V, or the second gate electrode 519 may be in a floating state.

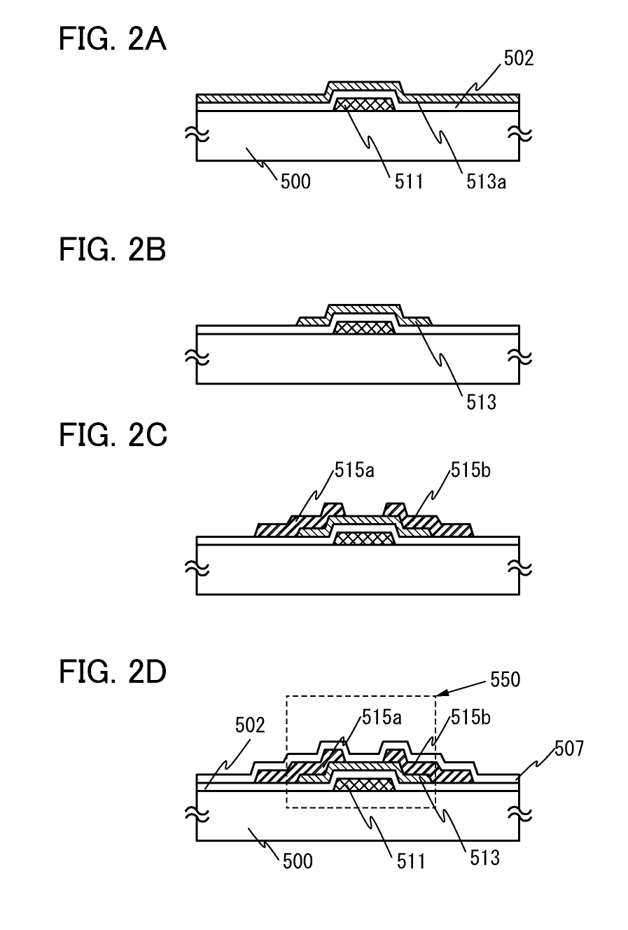

Next, a manufacturing method of the transistor 550 over the substrate 500 will be described with reference to FIGS. 2A to 2D.

First, after a conductive film is formed over the substrate 500 having an insulating surface, a wiring layer including the first gate electrode 511 is formed by a first photolithography step. Note that a resist mask may be formed by an inkjet method. Formation of the resist mask by an inkjet method needs no photomask; thus, manufacturing cost can be reduced.

In this embodiment, as the substrate 500 having an insulating surface, a glass substrate is used.

An insulating film serving as a base film may be provided between the substrate 500 and the first gate electrode 511. The base film has a function of preventing diffusion of an impurity element from the substrate 500, and can be formed to have a single-layer structure or a stacked-layer structure including one or more of a silicon nitride film, a silicon oxide film, a silicon nitride oxide film, and a silicon oxynitride film.

In addition, the first gate electrode 511 can be formed to have a single-layer structure or a stacked-layer structure using any of metal materials such as molybdenum, titanium, tantalum, tungsten, aluminum, copper, neodymium, and scandium, or an alloy material which contains any of these materials as a main component.

Next, the gate insulating layer 502 is formed over the first gate electrode 511. The gate insulating layer 502 is preferably formed using a material containing a Group 13 element and oxygen. For example, a material containing one or more of gallium oxide, aluminum oxide, aluminum gallium oxide, and gallium aluminum oxide; or the like can be used. Further, the gate insulating layer 502 can contain oxygen and a plurality of kinds of Group 13 elements. Alternatively, an impurity element other than hydrogen, e.g., a Group 3 element such as yttrium, a Group 4 element such as hafnium, a Group 14 element such as silicon, or the like can be contained instead of a Group 13 element. Such an impurity element is contained at about higher than 0 atomic % and lower than or equal to 20 atomic %, for example, whereby an energy gap of the gate insulating layer 502 can be controlled with the additive amount of the element.

The gate insulating layer 502 may alternatively be formed using silicon oxide or hafnium oxide.

The gate insulating layer 502 is preferably formed by a method with which impurities such as nitrogen, hydrogen, or water do not enter the gate insulating layer 502. This is because, when impurities such as nitrogen, hydrogen, or water are included in the gate insulating layer 502, the impurities such as nitrogen, hydrogen, or water enter the oxide semiconductor film formed later or oxygen in the oxide semiconductor film is extracted by the impurities such as hydrogen or water, so that the oxide semiconductor film might have lower resistance (have n-type conductivity) and a parasitic channel might be formed. Therefore, the gate insulating layer 502 is preferably formed so as to include impurities such as nitrogen, hydrogen, or water as little as possible. For example, the gate insulating layer 502 is preferably formed by a sputtering method. A high-purity gas from which an impurity such as nitrogen, hydrogen, or water is removed is preferable for a sputtering gas used in film formation.

Examples of the sputtering method include a DC sputtering method in which a direct current power source is used, a pulsed DC sputtering method in which a direct bias is applied in a pulsed manner, an AC sputtering method, and the like.

Note that in the case where an aluminum gallium oxide film or a gallium aluminum oxide film is formed as the gate insulating layer 502, a gallium oxide target to which an aluminum particle is added may be applied as a target used in a sputtering method. Using a gallium oxide target to which an aluminum particle is added can make conductivity of the target increase; thus, discharge during sputtering can be facilitated. With such a target, a metal oxide film suitable for mass production can be manufactured.

Then, the gate insulating layer 502 is preferably subjected to oxygen doping treatment. “Oxygen doping” refers to addition of oxygen into a bulk. Note that the term “bulk” is used in order to clarify that oxygen is added not only to a surface of a thin film but also to the inside of the thin film. In addition, “oxygen doping” includes “oxygen plasma doping” in which oxygen which is made to be plasma is added to a bulk.

Oxygen doping treatment is performed on the gate insulating layer 502, whereby a region containing oxygen with a higher proportion than that in the stoichiometric composition is formed in the gate insulating layer 502. Providing such a region allows oxygen to be supplied to the oxide semiconductor film which is formed later, and accordingly, oxygen defects in the oxide semiconductor film can be reduced.

In the case of using a gallium oxide film as the gate insulating layer 502, the composition Ga₂Oₓ (x=3+α, 0<α<1) can be obtained by oxygen doping. X may be more than or equal to 3.3 and less than or equal to 3.4, for example. In the case of using an aluminum oxide film as the gate insulating layer 502, the composition Al₂Oₓ (x=3+α, 0<α<1) can be obtained by oxygen doping. In the case of using an aluminum gallium oxide film as the gate insulating layer 502, the composition GaₓAl₂₋ₓO_{3+α} (0<x<1, 0<α<1) can be obtained by oxygen doping. Alternatively, in the case of using a gallium aluminum oxide film as the gate insulating layer 502, the composition GaₓAl₂₋ₓO_{3+α} (1<x≦2, 0<α<1) can be obtained by oxygen doping.

Next, an oxide semiconductor film 513a having a thickness of greater than or equal to 3 nm and less than or equal to 30 nm is formed over the gate insulating layer 502 by a sputtering method (see FIG. 2A). The thickness in the above range is preferable because when the thickness of the oxide semiconductor film 513a is too large (for example, when the thickness is 50 nm or more), the transistor might be normally on. Note that the gate insulating layer 502 and the oxide semiconductor film 513a are preferably formed successively without exposure to air.

As an oxide semiconductor used for the oxide semiconductor film 513a, the following metal oxide can be used: a four-component metal oxide such as an In—Sn—Ga—Zn—O based oxide semiconductor; a three-component metal oxide such as an In—Ga—Zn—O based oxide semiconductor, an In—Sn—Zn—O based oxide semiconductor, an In—Al—Zn—O based oxide semiconductor, a Sn—Ga—Zn—O based oxide semiconductor, an Al—Ga—Zn—O based oxide semiconductor, or a Sn—Al—Zn—O based oxide semiconductor; a two-component metal oxide such as an In—Zn—O based oxide semiconductor, a Sn—Zn—O based oxide semiconductor, an Al—Zn—O based oxide semiconductor, a Zn—Mg—O based oxide semiconductor, a Sn—Mg—O based oxide semiconductor, an In—Ga—O based oxide semiconductor, or an In—Mg—O based oxide semiconductor; an one-component metal oxide such as an In—O based oxide semiconductor, a Sn—O based oxide semiconductor, or a Zn—O based oxide semiconductor; or the like. Further, SiO₂ may be contained in the above oxide semiconductor. Note that here, for example, an In—Ga—Zn—O-based oxide semiconductor means an oxide semiconductor containing indium (In), gallium (Ga), and zinc (Zn), and there is no particular limitation on the stoichiometric proportion. The In—Ga—Zn—O-based oxide semiconductor may contain an element other than In, Ga, and Zn.

In addition, as the oxide semiconductor film 513a, a thin film of a material represented by the chemical formula, InMO₃(ZnO)ₘ (m>0), can be used. Here, M represents one or more metal elements selected from Ga, Al, Mn, and Co. For example, M can be Ga, Ga and Al, Ga and Mn, Ga and Co, or the like.

In the case where an In—Zn—O-based material is used as an oxide semiconductor, a composition ratio of a target is In:Zn=50:1 to 1:2 in an atomic ratio (In₂O₃:ZnO=25:1 to 1:4 in a molar ratio), preferably, In:Zn=20:1 to 1:1 in an atomic ratio (In₂O₃:ZnO=10:1 to 1:2 in a molar ratio), further preferably, In:Zn=15:1 to 1.5:1 in an atomic ratio (In₂O₃:ZnO=15:2 to 3:4 in a molar ratio). For example, in a target used for formation of an In—Zn—O-based oxide semiconductor which has an atomic ratio of In:Zn:O=X:Y:Z, the relation of Z>1.5X+Y is satisfied.

In this embodiment, the oxide semiconductor film 513a is formed by a sputtering method with the use of an In—Ga—Zn—O-based oxide target. Further, the oxide semiconductor film 513a can be formed by a sputtering method in a rare gas (typically, argon) atmosphere, an oxygen atmosphere, or a mixed atmosphere of a rare gas and oxygen.

As a target used for forming an In—Ga—Zn—O film as the oxide semiconductor film 513a by a sputtering method, for example, an oxide target with the following composition ratio may be used: In₂O₃:Ga₂O₃:ZnO=1:1:1 [molar ratio]. Further, a material and a composition of the target are not limited to the above. For example, an oxide target having a composition ratio of In₂O₃:Ga₂O₃:ZnO=1:1:2 [molar ratio] may be used.

The filling rate of the oxide target is higher than or equal to 90% and lower than or equal to 100%, preferably higher than or equal to 95% and lower than or equal to 99.9%. With the use of the metal oxide target with high filling rate, the oxide semiconductor film 513a can be a dense film.

It is preferable that a high-purity gas from which an impurity such as nitrogen, hydrogen, water, a hydroxyl group, or a hydride is removed be used as the sputtering gas used for the formation of the oxide semiconductor film 513a.

For the formation of the oxide semiconductor film 513a, the substrate 500 is held in a deposition chamber kept under reduced pressure, and the substrate temperature is set to a temperature of higher than or equal to 100° C. and lower than or equal to 600° C., preferably higher than or equal to 200° C. and lower than or equal to 400° C. Film formation is performed while the substrate 500 is being heated, whereby the concentration of an impurity contained in the formed oxide semiconductor film 513a can be reduced. In addition, damage by sputtering can be reduced. Then, a sputtering gas from which hydrogen and water are removed is introduced into the deposition chamber from which remaining moisture is being removed, so that the oxide semiconductor film 513a is formed over the substrate 500 with the use of the above target. In order to remove moisture remaining in the deposition chamber, an entrapment vacuum pump such as a cryopump, an ion pump, or a titanium sublimation pump is preferably used. Further, an evacuation unit may be a turbo pump provided with a cold trap. In the deposition chamber which is evacuated with the cryopump, for example, a hydrogen atom, a compound containing a hydrogen atom, such as water, nitrogen, (more preferably, also a compound containing a carbon atom), and the like are removed, whereby the concentration of an impurity in the oxide semiconductor film 513a formed in the deposition chamber can be reduced.

As one example of the deposition condition, the distance between the substrate and the target is 100 mm, the pressure is 0.6 Pa, the direct-current (DC) power source is 0.5 kW, and the atmosphere is an oxygen atmosphere (the proportion of the oxygen flow rate is 100%). Note that a pulsed direct-current power source is preferably used, in which case powder substances (also referred to as particles or dust) that are generated in deposition can be reduced and the film thickness can be uniform.

After that, heat treatment (first heat treatment) is desirably performed on the oxide semiconductor film 513a. By the first heat treatment, excessive hydrogen (including water and a hydroxyl group) in the oxide semiconductor film 513a can be removed. Moreover, excessive hydrogen (including water and a hydroxyl group) in the gate insulating layer 502 can also be removed by the first heat treatment. The first heat treatment is performed at higher than or equal to 250° C. and lower than or equal to 700° C., preferably higher than or equal to 450° C. and lower than or equal to 600° C. or lower than the strain point of the substrate.

The heat treatment can be performed in such a way that, for example, an object to be heated is introduced into an electric furnace in which a resistance heating element or the like is used and heated at 450° C. for one hour under a nitrogen atmosphere. The oxide semiconductor film 513a is not exposed to the air during the heat treatment so that entry of water or hydrogen can be prevented.

The heat treatment apparatus is not limited to the electric furnace and may be an apparatus for heating an object by thermal radiation or thermal conduction from a medium such as a heated gas. For example, an RTA (rapid thermal anneal) apparatus such as a GRTA (gas rapid thermal anneal) apparatus or an LRTA (lamp rapid thermal anneal) apparatus can be used. An LRTA apparatus is an apparatus for heating an object to be processed by radiation of light (an electromagnetic wave) emitted from a lamp such as a halogen lamp, a metal halide lamp, a xenon arc lamp, a carbon arc lamp, a high pressure sodium lamp, or a high pressure mercury lamp. A GRTA apparatus is an apparatus for performing heat treatment using a high-temperature gas. As the gas, an inert gas which does not react with an object to be processed by heat treatment, such as nitrogen or a rare gas such as argon is used.

For example, as the first heat treatment, a GRTA process may be performed as follows. The object is put in an inert gas atmosphere that has been heated, heated for several minutes, and taken out from the inert gas atmosphere. The GRTA process enables high-temperature heat treatment in a short time. Moreover, the GRTA process can be employed even when the temperature exceeds the upper temperature limit of the object. Note that the inert gas may be switched to a gas including oxygen during the process. This is because defect levels in an energy gap due to oxygen vacancies can be reduced by performing the first heat treatment in an atmosphere including oxygen.

Note that as the inert gas atmosphere, an atmosphere that contains nitrogen or a rare gas (e.g., helium, neon, or argon) as its main component and does not contain water, hydrogen, or the like is preferably used. For example, the purity of nitrogen or a rare gas such as helium, neon, or argon introduced into a heat treatment apparatus is 6N (99.9999%) or higher, preferably 7N (99.99999%) or higher (that is, the concentration of the impurities is 1 ppm or lower, preferably 0.1 ppm or lower).

The above heat treatment (first heat treatment) can be referred to as dehydration treatment, dehydrogenation treatment, or the like because of its effect of removing hydrogen, water, and the like. The dehydration treatment or dehydrogenation treatment may be performed at the timing, for example, after the oxide semiconductor film 513a is processed to have an island shape. Such dehydration treatment or dehydrogenation treatment may be conducted once or plural times.

The gate insulating layer 502 in contact with the oxide semiconductor film 513a has been subjected to oxygen doping treatment and thus includes an oxygen excess region. Thus, transfer of oxygen from the oxide semiconductor film 513a to the gate insulating layer 502 can be suppressed. In addition, the oxide semiconductor film 513a is formed to be in contact with the gate insulating layer 502 subjected to the oxygen doping treatment, whereby oxygen can be supplied from the gate insulating layer 502 to the oxide semiconductor film 513a. The oxygen supply from the gate insulating layer 502 to the oxide semiconductor film 513a is further promoted by performance of heat treatment in a state where the gate insulating layer 502 subjected to the oxygen doping treatment is in contact with the oxide semiconductor film 513a.

Note that the oxygen added to the gate insulating layer 502 and supplied to the oxide semiconductor film 513a preferably has at least partly a dangling bond of oxygen in the oxide semiconductor. This is because the dangling bond can be bonded with hydrogen left in the oxide semiconductor film to immobilize hydrogen (make hydrogen an immovable ion).

Next, the oxide semiconductor film 513a is preferably processed into the island-shaped oxide semiconductor layer 513 by a second photolithography step (FIG. 2B). A resist mask for forming the island-shaped oxide semiconductor layer 513 may be formed by an inkjet method. Formation of the resist mask by an inkjet method needs no photomask; thus, manufacturing cost can be reduced. Dry etching, wet etching, or both dry etching and wet etching may be performed for formation of the island-shaped oxide semiconductor layer 513.

Next, a conductive film for forming a source electrode and a drain electrode (including a wiring formed in the same layer as the source electrode and the drain electrode) is formed over the gate insulating layer 502 and the oxide semiconductor layer 513. The conductive film for forming the source electrode and the drain electrode may be formed using a heat-resistant metal which is unlikely to react with oxygen. It is particularly preferable that the conductive film include one or more of Mo, W, and Pt. Alternatively, Au, Cr, or the like can be used. The conductive film is preferably formed by a method with which nitrogen does not enter the conductive film.

A resist mask is formed over the conductive film in a third photolithography step, the first electrode 515a and the second electrode 515b are formed by selective etching, and then the resist mask is removed (see FIG. 2C). Light exposure at the time of the formation of the resist mask in the third photolithography step may be performed using ultraviolet light, KrF laser light, or ArF laser light. A channel length L of the transistor to be formed later depends on the distance between a lower end of the first electrode 515a and a lower end of the second electrode 515b which are adjacent to each other over the oxide semiconductor layer 513. When light exposure is performed for a channel length L of smaller than 25 nm, the light exposure when the resist mask is formed in the third photolithography step may be performed using extreme ultraviolet light having an extremely short wavelength of several nanometers to several tens of nanometers, for example. In the light exposure by extreme ultraviolet light, the resolution is high and the focus depth is large. Thus, the channel length L of the transistor formed later can be reduced, whereby the operation speed of a circuit can be increased.

In order to reduce the number of photomasks used in a photolithography step and reduce the number of photolithography steps, an etching step may be performed with the use of a resist mask formed using a multi-tone mask which is a light-exposure mask through which light is transmitted to have a plurality of intensities. A resist mask formed with the use of a multi-tone mask has a plurality of thicknesses and further can be changed in shape by etching; therefore, the resist mask can be used in a plurality of etching steps for processing into different patterns. Therefore, a resist mask corresponding to at least two kinds or more of different patterns can be formed by one multi-tone mask. Thus, the number of light-exposure masks can be reduced and the number of corresponding photolithography steps can be also reduced, whereby simplification of a process can be realized.

Note that it is preferable that etching conditions be optimized so as not to etch and divide the oxide semiconductor layer 513 when the conductive film is etched. However, it is difficult to obtain such an etching condition under which only the conductive film is etched and the oxide semiconductor layer 513 is not etched at all. In some cases, only part of the oxide semiconductor layer 513, e.g., 5% to 50% in thickness of the oxide semiconductor layer 513 is etched when the conductive film is etched, whereby the oxide semiconductor layer 513 having a groove portion (a recessed portion) is formed.

Next, by plasma treatment using a gas such as N₂O, N₂, or Ar, water or the like adsorbed to a surface of an exposed portion of the oxide semiconductor layer 513 may be removed. In the case where plasma treatment is performed, the oxide insulating layer 507 which is to be in contact with the oxide semiconductor layer 513 is preferably formed following the plasma treatment without exposure to the air.

Then, the oxide insulating layer 507 is formed so as to cover the first electrode 515a and the second electrode 515b and be contact with part of the oxide semiconductor layer 513 (FIG. 2D). The oxide insulating layer 507 can be formed using a material and step similar to those of the gate insulating layer 502.

Then, the oxide insulating layer 507 is preferably subjected to oxygen doping treatment. Oxygen doping treatment is performed on the oxide insulating layer 507, whereby a region containing oxygen with a higher proportion than that in the stoichiometric composition is formed in the oxide insulating layer 507. Providing such a region allows oxygen to be supplied to the oxide semiconductor layer, and accordingly, oxygen defects in the oxide semiconductor layer can be reduced.

After that, second heat treatment is preferably performed in the state where part of the oxide semiconductor layer 513 (channel formation region) is in contact with the oxide insulating layer 507. The second heat treatment is performed at higher than or equal to 250° C. and lower than or equal to 700° C., preferably higher than or equal to 450° C. and lower than or equal to 600° C. or lower than the strain point of the substrate.

The second heat treatment may be performed in an atmosphere of nitrogen, oxygen, dry air (air in which a water content is 20 ppm or less, preferably 1 ppm or less, more preferably 10 ppb or less), or a rare gas (argon, helium, or the like). Note that it is preferable that water, hydrogen, or the like be not contained in the atmosphere of nitrogen, oxygen, dry air, a rare gas, or the like. It is also preferable that the purity of nitrogen, oxygen, or the rare gas which is introduced into a heat treatment apparatus be set to be 6N (99.9999%) or higher, preferably 7N (99.99999%) or higher (that is, the impurity concentration is 1 ppm or lower, preferably 0.1 ppm or lower).

The second heat treatment is performed while the oxide semiconductor layer 513 is in contact with the gate insulating layer 502 and the oxide insulating layer 507. Thus, oxygen which is one of main components of the oxide semiconductor and may be reduced due to the dehydration (or dehydrogenation) treatment can be supplied from the gate insulating layer 502 and the oxide insulating layer 507, which are films containing oxygen, to the oxide semiconductor layer 513. Through the above steps, the highly-purified oxide semiconductor layer 513 which is electrically i-type (intrinsic) can be formed.

As described above, at least one of the first heat treatment and the second heat treatment is applied, whereby the oxide semiconductor layer 513 can be highly purified so as to contain impurities other than main components as little as possible. The highly-purified oxide semiconductor layer 513 contains extremely few (close to zero) carriers derived from a donor, and the carrier concentration thereof is lower than 1×10¹⁴/cm³, preferably lower than 1×10¹²/cm³, further preferably lower than 1×10¹¹/cm³.

Through the above process, the transistor 550 is formed. The transistor 550 includes the oxide semiconductor layer 513 which is highly purified and from which an impurity such as hydrogen, water, a hydroxyl group, or a hydride (also referred to as a hydrogen compound) is intentionally removed. Further, the nitrogen concentration of the oxide semiconductor layer 513 is sufficiently reduced (the nitrogen concentration is 2×10¹⁹ atoms/cm³ or lower). In addition, the first electrode 515a and the second electrode 515b include a metal which is unlikely to react with oxygen. Therefore, variation in the electric characteristics of the transistor 550 is suppressed and the transistor 550 is electrically stable.

Note that although not illustrated, a protective insulating film may be further formed so as to cover the transistor 550. As the protective insulating film, a silicon nitride film, a silicon nitride oxide film, an aluminum nitride film, or the like may be used.

A planarizing insulating film may be formed over the transistor 550. The planarizing insulating film can be formed using a heat-resistant organic material, such as acrylic, polyimide, benzocyclobutene, polyamide, or epoxy. Other than such organic materials, it is also possible to use a low-dielectric constant material (a low-k material), a siloxane-based resin, PSG (phosphosilicate glass), BPSG (borophosphosilicate glass), or the like. Note that the planarizing insulating film may be formed by stacking a plurality of insulating films formed of any of these materials.

In the case where the buffer layers 516a and 516b (or the buffer layers 516c and 516d) are formed over the oxide semiconductor layer 513 before formation of a conductive film to be a source electrode and a drain electrode later, the transistor 551a or 551b illustrated in FIG. 3A or 3B can be completed. As the buffer layer, a transparent conductive film such as an ITO film can be used, for example. A conductive film may be formed over the oxide semiconductor layer 513, a resist mask may be formed over the conductive film by a photolithography step, and selective etching may be performed, so that the buffer layers 516a and 516b may be formed, and then the resist mask may be removed.

Alternatively, the second gate electrode 519 is provided over the oxide insulating layer 507 to overlap with the channel formation region of the oxide semiconductor layer 513, whereby the transistor 552 illustrated in FIG. 4 can be completed. The second gate electrode 519 can be formed using a material and a step similar to those of the first gate electrode 511. The second gate electrode 519 is provided at a position overlapping with the channel formation region of the oxide semiconductor layer 513, whereby the amount of shift in the threshold voltage of the transistor between before and after the BT test can be reduced. Note that the potential of the second gate electrode 519 may be the same as or different from that of the first gate electrode 511. Alternatively, the potential of the second gate electrode 519 may be GND, 0 V, or the second gate electrode 519 may be in a floating state.

As described above, in the transistor of one embodiment of the present invention, the nitrogen concentration in the oxide semiconductor layer is set low and a heat-resistant metal which is unlikely to be oxidized is used for the source electrode and the drain electrode, so that bonding between oxygen and metal in the oxide semiconductor layer can be prevented from being inhibited. Thus, electric characteristics and reliability of the transistor including the oxide semiconductor can be improved. For example, variation in transistor characteristics due to light deterioration can be reduced.

### Embodiment 2

A semiconductor device (also referred to as a display device) with a display function can be manufactured using the transistor an example of which is described in Embodiment 1. Moreover, some or all of the driver circuits which include the transistors can be formed over a substrate where the pixel portion is formed, whereby a system-on-panel can be obtained.

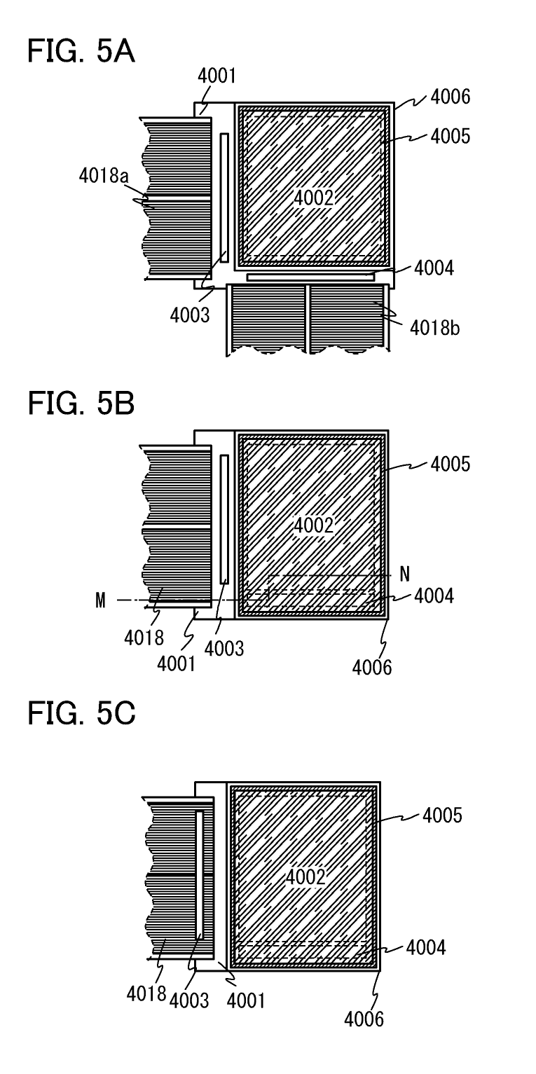

In FIG. 5A, a sealant 4005 is provided so as to surround a pixel portion 4002 provided over a first substrate 4001, and the pixel portion 4002 is sealed between the first substrate 4001 and the second substrate 4006. In FIG. 5A, a signal line driver circuit 4003 and a scan line driver circuit 4004 which are formed using a single crystal semiconductor film or a polycrystalline semiconductor film over a substrate separately prepared are mounted in a region that is different from the region surrounded by the sealant 4005 over the first substrate 4001. Various signals and potential are supplied to the signal line driver circuit 4003 and the scan line driver circuit 4004 each of which is separately formed, and the pixel portion 4002 from flexible printed circuits (FPCs) 4018a and 4018b.

In FIGS. 5B and 5C, the sealant 4005 is provided so as to surround the pixel portion 4002 and the scan line driver circuit 4004 which are provided over the first substrate 4001. The second substrate 4006 is provided over the pixel portion 4002 and the scan line driver circuit 4004. Consequently, the pixel portion 4002 and the scan line driver circuit 4004 are sealed together with a display element, by the first substrate 4001, the sealant 4005, and the second substrate 4006. In FIGS. 5B and 5C, the signal line driver circuit 4003 which is formed using a single crystal semiconductor film or a polycrystalline semiconductor film over a substrate separately prepared is mounted in a region that is different from the region surrounded by the sealant 4005 over the first substrate 4001. In FIGS. 5B and 5C, various signals and potential are supplied to the signal line driver circuit 4003 which is separately formed, the scan line driver circuit 4004, and the pixel portion 4002 from an FPC 4018.

Although FIGS. 5B and 5C each illustrate the example in which the signal line driver circuit 4003 is formed separately and mounted on the first substrate 4001, the present invention is not limited to this structure. The scan line driver circuit may be separately formed and then mounted, or only part of the signal line driver circuit or part of the scan line driver circuit may be separately formed and then mounted.

Note that a connection method of a separately formed driver circuit is not particularly limited, and a chip on glass (COG) method, a wire bonding method, a tape automated bonding (TAB) method, or the like can be used. FIG. 5A illustrates an example in which the signal line driver circuit 4003 and the scan line driver circuit 4004 are mounted by a COG method. FIG. 5B illustrates an example in which the signal line driver circuit 4003 is mounted by a COG method. FIG. 5C illustrates an example in which the signal line driver circuit 4003 is mounted by a TAB method.

In addition, the display device includes a panel in which the display element is sealed, and a module in which an IC or the like including a controller is mounted on the panel.

Note that a display device in this specification means an image display device, a display device, or a light source (including a lighting device). Furthermore, the display device also includes the following modules in its category: a module to which a connector such as an FPC, a TAB tape, or a TCP is attached; a module having a TAB tape or a TCP at the tip of which a printed wiring board is provided; and a module in which an integrated circuit (IC) is directly mounted on a display element by a COG method.

Further, the pixel portion and the scan line driver circuit which are provided over the first substrate include a plurality of transistors, and the transistor of one embodiment of the present invention, an example of which is described in Embodiment 1 can be applied thereto.

As the display element provided in the display device, a liquid crystal element (also referred to as a liquid crystal display element) or a light-emitting element (also referred to as a light-emitting display element) can be used. The light-emitting element includes, in its category, an element whose luminance is controlled by a current or a voltage, and specifically includes, in its category, an inorganic electroluminescent (EL) element, an organic EL element, and the like. Furthermore, a display medium whose contrast is changed by an electric effect, such as electronic ink, can be used.

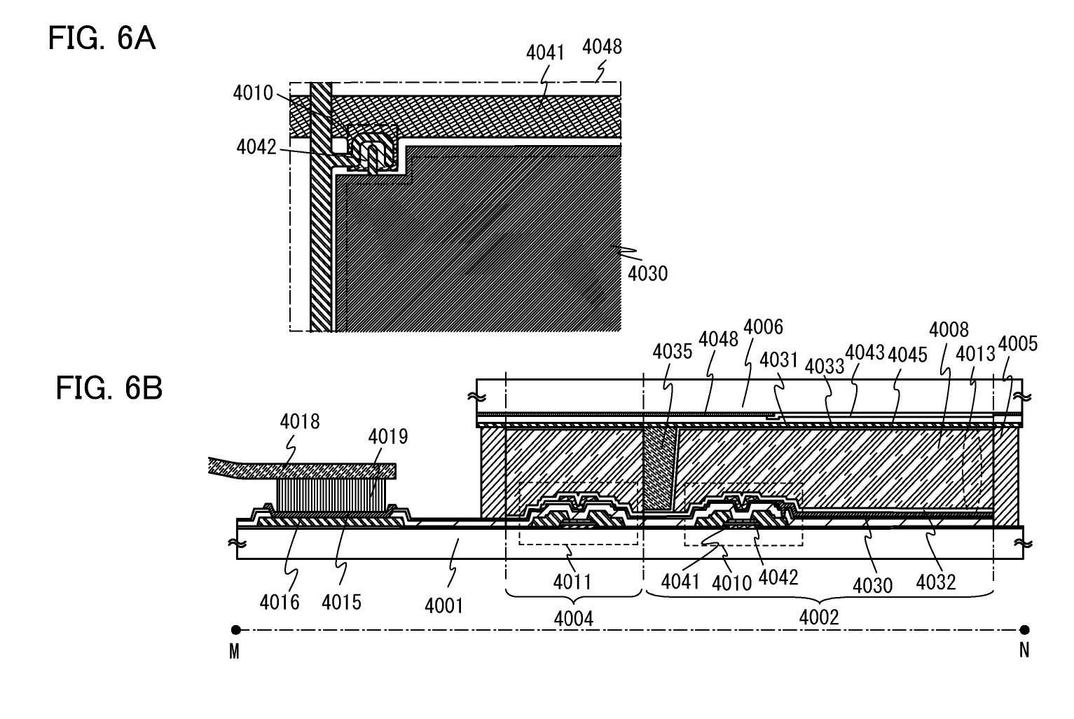

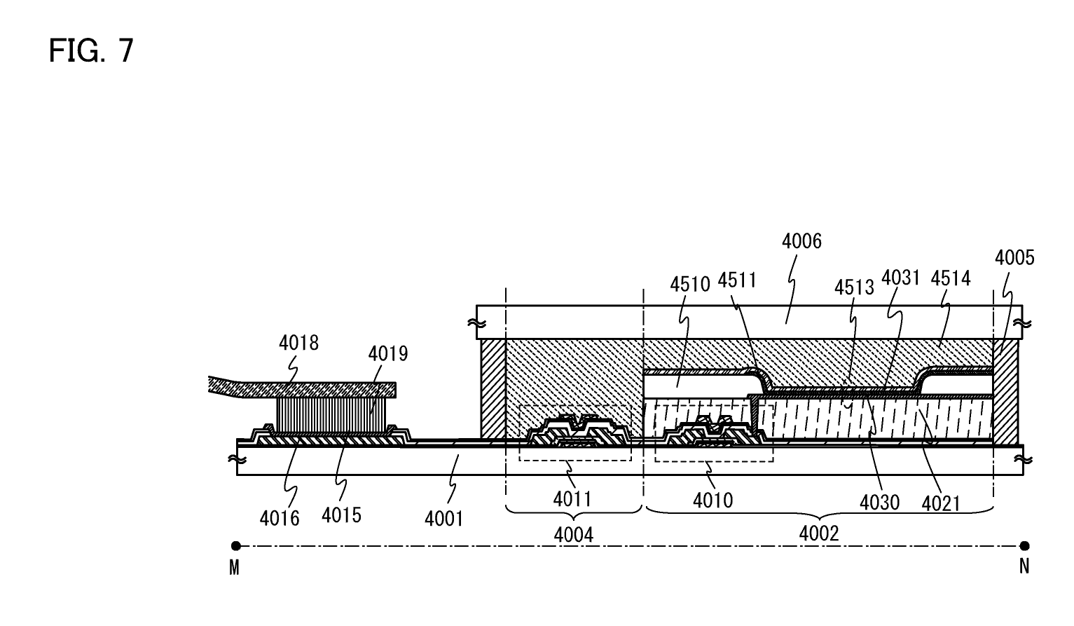

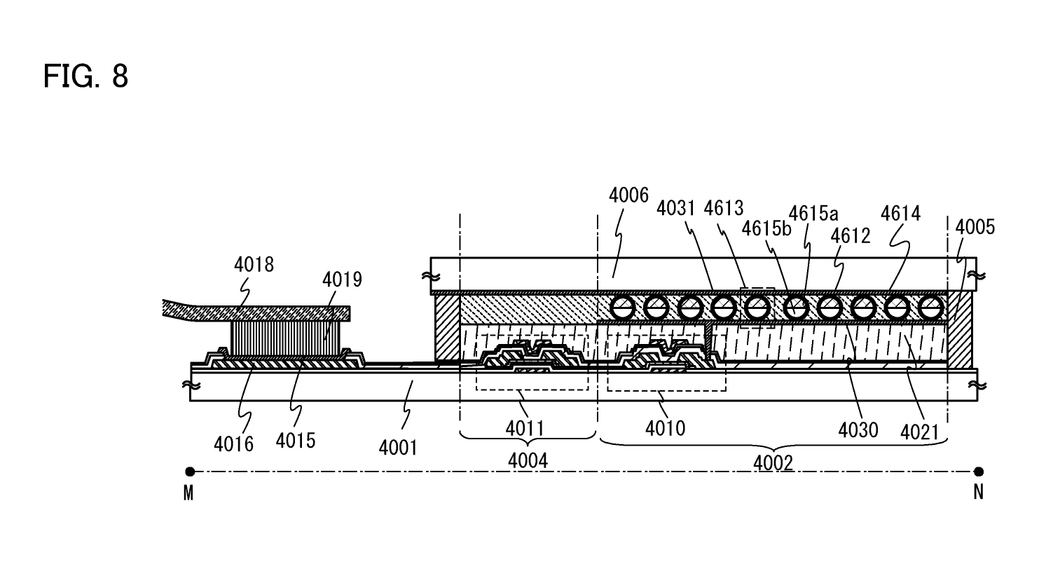

One embodiment of the semiconductor device is described with reference to FIGS. 6A and 6B, FIG. 7, and FIG. 8. FIG. 6B, FIG. 7, and FIG. 8 correspond to cross-sectional views along line M-N in FIG. 5B. FIG. 6A corresponds to a top view of a transistor 4010 illustrated in FIG. 6B.

As illustrated in FIGS. 6A and 6B, FIG. 7, and FIG. 8, the semiconductor device includes a connection terminal electrode 4015 and a terminal electrode 4016. The connection terminal electrode 4015 and the terminal electrode 4016 are electrically connected to a terminal included in the FPC 4018 through an anisotropic conductive film 4019.

The connection terminal electrode 4015 is formed using the same conductive film as a first electrode 4030, and the terminal electrode 4016 is formed using the same conductive film as source and drain electrodes of the transistor 4010 and a transistor 4011.

Each of the pixel portion 4002 and the scan line driver circuit 4004 which are provided over the first substrate 4001 includes a plurality of transistors. In FIGS. 6A and 6B, FIG. 7, and FIG. 8, the transistor 4010 included in the pixel portion 4002 and the transistor 4011 included in the scan line driver circuit 4004 are illustrated as an example.

As the transistor 4010 and the transistor 4011, the transistor of one embodiment of the present invention can be used. The transistor of one embodiment of the present invention has suppressed variation in electric characteristics and is electrically stable. Accordingly, highly reliable semiconductor devices can be provided as the semiconductor devices of this embodiment illustrated in FIGS. 6A and 6B, FIG. 7, and FIG. 8.

The transistor 4010 included in the pixel portion 4002 is electrically connected to a display element to form a display panel. A variety of display elements can be used as the display element as long as display can be performed.

An example of a liquid crystal display device using a liquid crystal element as a display element is described in FIGS. 6A and 6B. In FIGS. 6A and 6B, a liquid crystal element 4013 which is a display element includes the first electrode 4030, a second electrode 4031, and a liquid crystal layer 4008. Insulating films 4032 and 4033 serving as alignment films are provided so that the liquid crystal layer 4008 is interposed therebetween. The second electrode 4031 is formed on the second substrate 4006 side. The first electrode 4030 and the second electrode 4031 are stacked with the liquid crystal layer 4008 interposed therebetween. In a region where the first electrode 4030 and the second electrode 4031 do not overlap with each other, a light-blocking layer 4048 (a black matrix) is provided on the second substrate 4006 side. In a region where the first electrode 4030 and the second electrode 4031 overlap with each other, a color filter layer 4043 is provided. A planarization film 4045 is formed between the second electrode 4031, and the light-blocking layer 4048 and the color filter layer 4043.

In each of the transistors 4010 and 4011 in FIGS. 6A and 6B, a gate electrode is positioned so as to cover the lower side of an oxide semiconductor layer (see a gate electrode 4041 and an oxide semiconductor layer 4042 in the transistor 4010), and the light-blocking layer 4048 is positioned so as to overlap with the upper side of the oxide semiconductor layer. Thus, light can be blocked at both the upper side and the lower side in each of the transistors 4010 and 4011. The blocking of light can reduce stray light which enters channel formation regions of the transistors 4010 and 4011 and suppress deterioration of transistor characteristics. Specifically, variation in threshold voltage can be suppressed even when the oxide semiconductor is used for the channel formation regions.

A columnar spacer denoted by reference numeral 4035 is obtained by selective etching of an insulating film and is provided in order to control the thickness (a cell gap) of the liquid crystal layer 4008. Alternatively, a spherical spacer may be used.

In the case where a liquid crystal element is used as the display element, a thermotropic liquid crystal, a low-molecular liquid crystal, a high-molecular liquid crystal, a polymer dispersed liquid crystal, a ferroelectric liquid crystal, an anti-ferroelectric liquid crystal, or the like can be used. These liquid crystal materials exhibit a cholesteric phase, a smectic phase, a cubic phase, a chiral nematic phase, an isotropic phase, or the like depending on conditions.

Alternatively, liquid crystal exhibiting a blue phase for which an alignment film is unnecessary may be used. A blue phase is one of liquid crystal phases, which is generated just before a cholesteric phase changes into an isotropic phase while temperature of cholesteric liquid crystal is increased. Since the blue phase appears only in a narrow temperature range, a liquid crystal composition in which 5 wt. % or more of a chiral material is mixed is used for the liquid crystal layer in order to improve the temperature range. The liquid crystal composition which includes a liquid crystal showing a blue phase and a chiral agent has a short response time of 1 msec or less and is optically isotropic; thus, alignment treatment is not necessary and viewing angle dependence is small. In addition, since an alignment film does not need to be provided and rubbing treatment is unnecessary, electrostatic discharge damage caused by the rubbing treatment can be prevented and defects and damage of the liquid crystal display device can be reduced in the manufacturing process. Thus, productivity of the liquid crystal display device can be increased.

The specific resistivity of the liquid crystal material is 1×10⁹ Ω·cm or more, preferably 1×10¹¹ Ω·cm or more, further preferably 1×10¹² Ω·cm or more. The value of the specific resistivity in this specification is measured at 20° C.

The size of a storage capacitor formed in the liquid crystal display device is set considering the leakage current of the transistor provided in the pixel portion or the like so that charge can be held for a predetermined period. By using the transistor including the high-purity oxide semiconductor film, it is enough to provide a storage capacitor having a capacitance that is ⅓ or less, preferably ⅕ or less of a liquid crystal capacitance of each pixel.

In the transistor used in this embodiment, which includes the highly purified oxide semiconductor film, the current in an off state (the off-state current) can be made small. Accordingly, an electrical signal such as an image signal can be held for a longer period, and a writing interval can be set longer in an on state. Accordingly, frequency of refresh operation can be reduced, which leads to an effect of suppressing power consumption.

In addition, the transistor including the highly purified oxide semiconductor film used in this embodiment can have relatively high field-effect mobility and thus can operate at high speed. Therefore, by using the transistor in a pixel portion of a liquid crystal display device, a high-quality image can be provided. In addition, since the transistors can be separately provided in a driver circuit portion and a pixel portion over one substrate, the number of components of the liquid crystal display device can be reduced.

For the liquid crystal display device, a twisted nematic (TN) mode, an in-plane-switching (IPS) mode, a fringe field switching (FFS) mode, an axially symmetric aligned micro-cell (ASM) mode, an optical compensated birefringence (OCB) mode, a ferroelectric liquid crystal (FLC) mode, an antiferroelectric liquid crystal (AFLC) mode, or the like can be used.

A normally black liquid crystal display device such as a transmissive liquid crystal display device utilizing a vertical alignment (VA) mode may be used. The vertical alignment mode is a method of controlling alignment of liquid crystal molecules of a liquid crystal display panel, in which liquid crystal molecules are aligned vertically to a panel surface when no voltage is applied. Some examples are given as the vertical alignment mode. For example, a multi-domain vertical alignment (MVA) mode, a patterned vertical alignment (PVA) mode, an Advanced Super View (ASV) mode, or the like can be used. Moreover, it is possible to use a method called domain multiplication or multi-domain design, in which a pixel is divided into some regions (subpixels) and molecules are aligned in different directions in their respective regions.

In the display device, an optical member (an optical substrate) such as a polarizing member, a retardation member, or an anti-reflection member, and the like are provided as appropriate. For example, circular polarization may be obtained by using a polarizing substrate and a retardation substrate. In addition, a backlight, a side light, or the like may be used as a light source.

In addition, it is possible to employ a time-division display method (also called a field-sequential driving method) with the use of a plurality of light-emitting diodes (LEDs) as a backlight. By employing a field-sequential driving method, color display can be performed without using a color filter.

As a display method in the pixel portion, a progressive method, an interlace method or the like can be employed. Further, color elements controlled in a pixel at the time of color display are not limited to three colors: R, G, and B (R, G, and B correspond to red, green, and blue, respectively). For example, R, G, B, and W (W corresponds to white); R, G, B, and one or more of yellow, cyan, magenta, and the like; or the like can be used. Further, the sizes of display regions may be different between respective dots of color elements. The present invention is not limited to the application to a display device for color display but can also be applied to a display device for monochrome display.

Alternatively, as the display element included in the display device, a light-emitting element utilizing electroluminescence can be used. Light-emitting elements utilizing electroluminescence are classified according to whether a light-emitting material is an organic compound or an inorganic compound. In general, the former is referred to as an organic EL element, and the latter is referred to as an inorganic EL element.

In an organic EL element, by application of voltage to a light-emitting element, electrons and holes are separately injected from a pair of electrodes into a layer containing a light-emitting organic compound, and current flows. The carriers (electrons and holes) are recombined, and thus, the light-emitting organic compound is excited. The light-emitting organic compound returns to a ground state from the excited state, thereby emitting light. Owing to such a mechanism, this light-emitting element is referred to as a current-excitation light-emitting element.

The inorganic EL elements are classified according to their element structures into a dispersion-type inorganic EL element and a thin-film inorganic EL element. A dispersion-type inorganic EL element has a light-emitting layer where particles of a light-emitting material are dispersed in a binder, and its light emission mechanism is donor-acceptor recombination type light emission that utilizes a donor level and an acceptor level. A thin-film inorganic EL element has a structure where a light-emitting layer is sandwiched between dielectric layers, which are further sandwiched between electrodes, and its light emission mechanism is localized type light emission that utilizes inner-shell electron transition of metal ions. Note that an example of an organic EL element as a light-emitting element is described here.

In order to extract light emitted from the light-emitting element, it is acceptable as long as at least one of a pair of electrodes is transparent. The light-emitting element can have a top emission structure in which light emission is extracted through the surface opposite to the substrate; a bottom emission structure in which light emission is extracted through the surface on the substrate side; or a dual emission structure in which light emission is extracted through the surface opposite to the substrate and the surface on the substrate side, and a light-emitting element having any of these emission structures can be used.

FIG. 7 illustrates an example of a light-emitting device in which a light-emitting element is used as a display element. A light-emitting element 4513 which is a display element is electrically connected to the transistor 4010 provided in the pixel portion 4002. A structure of the light-emitting element 4513 is not limited to the stacked-layer structure including the first electrode 4030, an electroluminescent layer 4511, and the second electrode 4031. The structure of the light-emitting element 4513 can be changed as appropriate depending on a direction in which light is extracted from the light-emitting element 4513, or the like.

A partition wall 4510 can be formed using an organic insulating material or an inorganic insulating material. It is particularly preferable that the partition wall 4510 be formed using a photosensitive resin material to have an opening over the first electrode 4030 so that a sidewall of the opening has a tilted surface with continuous curvature.

The electroluminescent layer 4511 may be formed using a single layer or a plurality of layers stacked.

A protective film may be formed over the second electrode 4031 and the partition wall 4510 in order to prevent entry of oxygen, hydrogen, water, carbon dioxide, or the like into the light-emitting element 4513. As the protective film, a silicon nitride film, a silicon nitride oxide film, a DLC film, or the like can be formed. In addition, in a space which is formed with the first substrate 4001, the second substrate 4006, and the sealant 4005, a filler 4514 is provided for sealing. It is preferable that a panel be packaged (sealed) with a protective film (such as a laminate film or an ultraviolet curable resin film) or a cover material with high air-tightness and little degasification so that the panel is not exposed to the outside air, in this manner.

As the filler 4514, an ultraviolet curable resin or a thermosetting resin can be used as well as an inert gas such as nitrogen or argon. For example, poly(vinyl chloride) (PVC), acrylic, polyimide, an epoxy resin, a silicone resin, poly(vinyl butyral) (PVB), or ethylene with vinyl acetate (EVA) can be used. For example, nitrogen may be used for the filler.

In addition, if needed, an optical film, such as a polarizing plate, a circularly polarizing plate (including an elliptically polarizing plate), a retardation plate (a quarter-wave plate or a half-wave plate), or a color filter, may be provided as appropriate on a light-emitting surface of the light-emitting element. Further, the polarizing plate or the circularly polarizing plate may be provided with an anti-reflection film. For example, anti-glare treatment by which reflected light can be diffused by projections and depressions on the surface so as to reduce the glare can be performed.

Further, an electronic paper in which electronic ink is driven can be provided as the display device. The electronic paper is also referred to as an electrophoretic display device (an electrophoretic display) and is advantageous in that it has the same level of readability as plain paper, it has lower power consumption than other display devices, and it can be made thin and lightweight.

An electrophoretic display device can have various modes. An electrophoretic display device contains a plurality of microcapsules dispersed in a solvent or a solute, each microcapsule containing first particles which are positively charged and second particles which are negatively charged. By applying an electric field to the microcapsules, the particles in the microcapsules move in opposite directions to each other and only the color of the particles gathering on one side is displayed. Note that the first particles and the second particles each contain pigment and do not move without an electric field. Moreover, the first particles and the second particles have different colors (which may be colorless).

Thus, an electrophoretic display device is a display device that utilizes a so-called dielectrophoretic effect by which a substance having a high dielectric constant moves to a high-electric field region.

A solution in which the above microcapsules are dispersed in a solvent is referred to as electronic ink This electronic ink can be printed on a surface of glass, plastic, cloth, paper, or the like. Furthermore, by using a color filter or particles that have a pigment, color display can also be achieved.

Note that the first particles and the second particles in the microcapsules may each be formed of a single material selected from a conductive material, an insulating material, a semiconductor material, a magnetic material, a liquid crystal material, a ferroelectric material, an electroluminescent material, an electrochromic material, and a magnetophoretic material, or formed of a composite material of any of these.

As the electronic paper, a display device using a twisting ball display system can be used. In the twisting ball display system, spherical particles each colored in black and white are arranged between a first electrode and a second electrode which are electrodes used for a display element, and a potential difference is generated between the first electrode and the second electrode to control orientation of the spherical particles, so that display is performed.

FIG. 8 illustrates an active matrix electronic paper as one embodiment of a semiconductor device. The electronic paper in FIG. 8 is an example of a display device using a twisting ball display system. The twist ball display system refers to a method in which spherical particles each colored in black and white are arranged between electrodes included in a display element, and a potential difference is generated between the electrodes to control the orientation of the spherical particles, so that display is performed.

Between the first electrode 4030 connected to the transistor 4010 and the second electrode 4031 provided on the second substrate 4006, spherical particles 4613 each of which includes a black region 4615a, a white region 4615b, and a cavity 4612 which is filled with liquid around the black region 4615a and the white region 4615b, are provided. A space around the spherical particles 4613 is filled with a filler 4614 such as a resin. The second electrode 4031 corresponds to a common electrode (counter electrode). The second electrode 4031 is electrically connected to a common potential line.

In FIGS. 6A and 6B, FIG. 7, and FIG. 8, as the first substrate 4001 and the second substrate 4006, flexible substrates, for example, plastic substrates having a light-transmitting property or the like can be used, as well as glass substrates. As plastic, a fiberglass-reinforced plastics (FRP) plate, a polyvinyl fluoride (PVF) film, a polyester film, or an acrylic resin film can be used. In addition, a sheet with a structure in which an aluminum foil is sandwiched between PVF films or polyester films can be used.

An insulating layer 4021 can be formed using an inorganic insulating material or an organic insulating material. Note that the insulating layer 4021 formed using a heat-resistant organic insulating material such as an acrylic resin, polyimide, a benzocyclobutene resin, polyamide, or an epoxy resin is preferably used as a planarizing insulating film. Other than such organic insulating materials, it is possible to use a low-dielectric constant material (a low-k material), a siloxane based resin, phosphosilicate glass (PSG), borophosphosilicate glass (BPSG), or the like. The insulating layer may be formed by stacking a plurality of insulating films formed of these materials.

There is no particular limitation on the method for forming the insulating layer 4021, and the insulating layer 4021 can be formed, depending on the material, by a sputtering method, a spin coating method, a dipping method, a spray coating method, a droplet discharge method (e.g., an inkjet method, screen printing, or offset printing), roll coating, curtain coating, knife coating, or the like.

The display device displays an image by transmitting light from a light source or a display element. Therefore, the substrate and the thin films such as the insulating film and the conductive film provided for the pixel portion where light is transmitted have light-transmitting properties with respect to light in the visible-light wavelength range.

The first electrode and the second electrode (each of which may be called a pixel electrode, a common electrode, a counter electrode, or the like) for applying voltage to the display element may have light-transmitting properties or light-reflecting properties, which depends on the direction in which light is extracted, the position where the electrode is provided, and the pattern structure of the electrode.

The first electrode 4030 and the second electrode 4031 can be formed using a light-transmitting conductive material such as indium oxide containing tungsten oxide, indium zinc oxide containing tungsten oxide, indium oxide containing titanium oxide, indium tin oxide containing titanium oxide, indium tin oxide (hereinafter referred to as ITO), indium zinc oxide, or indium tin oxide to which silicon oxide is added.

The first electrode 4030 and the second electrode 4031 can be formed of one or more kinds of materials selected from metals such as tungsten, molybdenum, zirconium, hafnium, vanadium, niobium, tantalum, chromium, cobalt, nickel, titanium, platinum, aluminum, copper, and silver; alloys of these metals; and nitrides of these metals.

A conductive composition including a conductive high molecule (also referred to as a conductive polymer) can be used for the first electrode 4030 and the second electrode 4031. As the conductive high molecule, a so-called π-electron conjugated conductive polymer can be used. For example, polyaniline or a derivative thereof, polypyrrole or a derivative thereof, polythiophene or a derivative thereof, a copolymer of two or more of aniline, pyrrole, and thiophene or a derivative thereof, and the like can be given.

Since the transistor is easily broken owing to static electricity or the like, a protective circuit for protecting the driver circuit is preferably provided. The protection circuit is preferably formed using a nonlinear element.

As described above, by using any of the transistors described in Embodiment 1, a semiconductor device having high reliability can be provided. Note that the transistors described in Embodiment 1 can be applied to not only semiconductor devices having the display functions described above but also semiconductor devices having a variety of functions, such as a power device which is mounted on a power supply circuit, a semiconductor integrated circuit such as an LSI, and a semiconductor device having an image sensor function of reading information of an object.

This embodiment can be implemented in appropriate combination with the structures described in the other embodiments.

### Embodiment 3

A semiconductor device disclosed in this specification can be applied to a variety of electronic devices (including game machines). Examples of electronic devices are a television set (also referred to as a television or a television receiver), a monitor of a computer or the like, a camera such as a digital camera or a digital video camera, a digital photo frame, a mobile phone handset (also referred to as a mobile phone or a mobile phone device), a portable game machine, a portable information terminal, an audio reproducing device, a large-sized game machine such as a pachinko machine, and the like. Examples of electronic devices each including the liquid crystal display device described in the above embodiment are described.

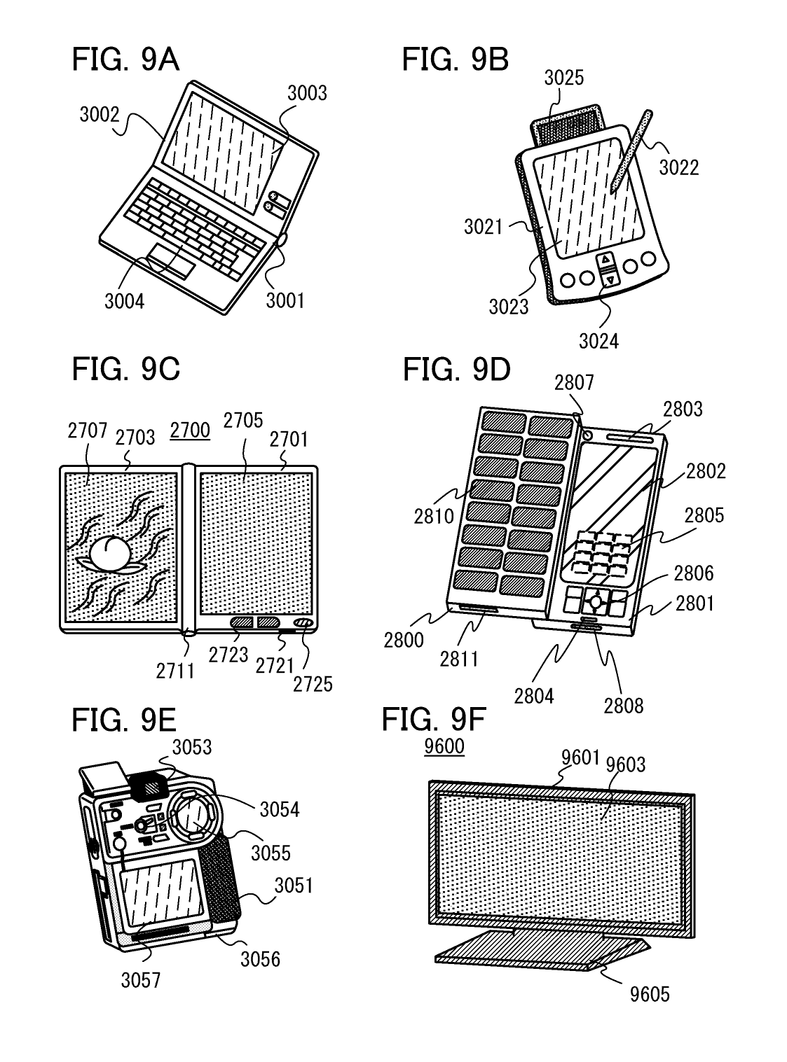

FIG. 9A is a laptop personal computer, which includes a main body 3001, a housing 3002, a display portion 3003, a keyboard 3004, and the like. By applying the semiconductor device of one embodiment of the present invention, the laptop personal computer can have high reliability.

FIG. 9B is a portable information terminal (PDA), which includes a display portion 3023, an external interface 3025, an operation button 3024, and the like in a main body 3021. A stylus 3022 is included as an accessory for operation. By applying the semiconductor device of one embodiment of the present invention, the portable information terminal (PDA) can have higher reliability.

FIG. 9C is an example of an e-book reader. For example, an e-book reader 2700 includes two housings, a housing 2701 and a housing 2703. The housing 2701 and the housing 2703 are combined with a hinge 2711 so that the e-book reader 2700 can be opened and closed with the hinge 2711 as an axis. With such a structure, the e-book reader 2700 can operate like a paper book.

A display portion 2705 and a display portion 2707 are incorporated in the housing 2701 and the housing 2703, respectively. The display portion 2705 and the display portion 2707 may display one image or different images. In the case where the display portion 2705 and the display portion 2707 display different images, for example, a display portion on the right side (the display portion 2705 in FIG. 9C) can display text and a display portion on the left side (the display portion 2707 in FIG. 9C) can display graphics. The semiconductor device of one embodiment of the present invention is applied, whereby the e-book reader 2700 can have high reliability.

Further, FIG. 9C illustrates an example in which the housing 2701 is provided with an operation portion and the like. For example, the housing 2701 is provided with a power switch 2721, operation keys 2723, a speaker 2725, and the like. With the operation keys 2723, pages can be turned. Note that a keyboard, a pointing device, or the like may also be provided on the surface of the housing, on which the display portion is provided. Furthermore, an external connection terminal (an earphone terminal, a USB terminal, or the like), a recording medium insertion portion, and the like may be provided on the back surface or the side surface of the housing. Moreover, the e-book reader 2700 may have a function of an electronic dictionary.

The e-book reader 2700 may have a configuration capable of wirelessly transmitting and receiving data. Through wireless communication, desired book data or the like can be purchased and downloaded from an electronic book server.

FIG. 9D is a mobile phone, which includes two housings, a housing 2800 and a housing 2801. The housing 2801 includes a display panel 2802, a speaker 2803, a microphone 2804, a pointing device 2806, a camera lens 2807, an external connection terminal 2808, and the like. In addition, the housing 2800 includes a solar cell 2810 having a function of charge of the portable information terminal, an external memory slot 2811, and the like. Further, an antenna is incorporated in the housing 2801. The semiconductor device of one embodiment of the present invention is applied, whereby a highly reliable mobile phone can be provided.

Further, the display panel 2802 is provided with a touch panel. A plurality of operation keys 2805 that is displayed as images is illustrated by dashed lines in FIG. 9D. Note that a boosting circuit by which a voltage output from the solar cell 2810 is increased to be sufficiently high for each circuit is also included.

In the display panel 2802, the display direction can be appropriately changed depending on a usage pattern. Further, the display device is provided with the camera lens 2807 on the same surface as the display panel 2802, and thus it can be used as a video phone. The speaker 2803 and the microphone 2804 can be used for videophone calls, recording and playing sound, and the like as well as voice calls. Further, the housings 2800 and 2801 in a state where they are developed as illustrated in FIG. 9D can shift by sliding so that one is lapped over the other; therefore, the size of the mobile phone can be reduced, which makes the mobile phone suitable for being carried.

The external connection terminal 2808 can be connected to an AC adapter and various types of cables such as a USB cable, and charging and data communication with a personal computer are possible. Moreover, a large amount of data can be stored by inserting a storage medium into the external memory slot 2811 and can be moved.

Further, in addition to the above functions, an infrared communication function, a television reception function, or the like may be provided.

FIG. 9E illustrates a digital video camera which includes a main body 3051, a display portion A 3057, an eyepiece 3053, an operation switch 3054, a display portion B 3055, a battery 3056, and the like. By applying the semiconductor device of one embodiment of the present invention, the digital video camera can have high reliability.

FIG. 9F illustrates an example of a television set. In a television set 9600, a display portion 9603 is incorporated in a housing 9601. The display portion 9603 can display images. Here, the housing 9601 is supported by a stand 9605. By employing the semiconductor device of one embodiment of the present invention, the television set 9600 can have high reliability.

The television set 9600 can be operated by an operation switch of the housing 9601 or a separate remote controller. Further, the remote controller may be provided with a display portion for displaying data output from the remote controller.

Note that the television set 9600 is provided with a receiver, a modem, and the like. With the use of the receiver, general television broadcasting can be received. Moreover, when the display device is connected to a communication network with or without wires via the modem, one-way (from a sender to a receiver) or two-way (between a sender and a receiver or between receivers) information communication can be performed.

This embodiment can be implemented in appropriate combination with the structures described in the other embodiments.

### Example 1

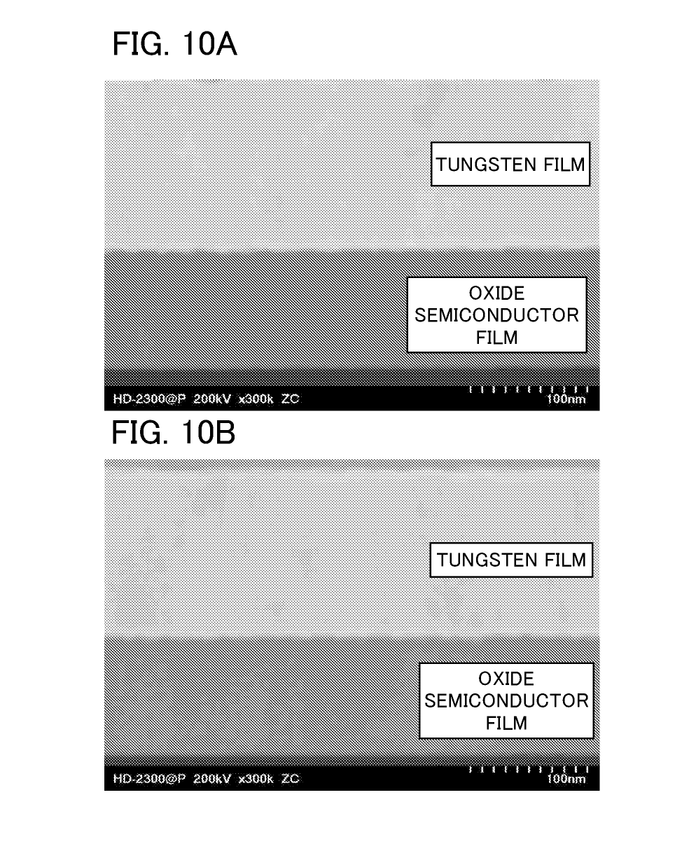

In this example, a substrate in which a tungsten film was formed over an oxide semiconductor film was prepared as a sample, and a cross section of the sample before and after bake treatment was observed. The cross-sectional observation of the sample will be described with reference to FIGS. 10A and 10B.

First, samples for performing cross-sectional observation were manufactured.

A 100-nm-thick oxide semiconductor film was formed over a glass substrate by a sputtering method using an In—Ga—Zn—O-based metal oxide target (In₂O₃:Ga₂O₃:ZnO=1:1:1 [molar ratio]) under a mixed atmosphere of argon and oxygen (argon:oxygen=30 sccm:15 sccm) at room temperature under the following conditions: the distance between the substrate and the target was 60 mm, the pressure was 0.4 Pa, and the direct current (DC) power was 5 kW.

Then, a 150-nm-thick tungsten film was formed over the oxide semiconductor film by a sputtering method using a tungsten target.

Through the above steps, a sample in which an oxide semiconductor film and a tungsten film were stacked over a glass substrate was obtained.

After that, the manufactured substrate was divided into two pieces, on one of which bake treatment was performed at 350° C. for one hour in an air atmosphere, with the use of an oven.

A sample on which bake treatment was not performed (sample 1) and the sample on which bake treatment was performed (sample 2) were both sliced, and cross sections thereof were observed using a scanning transmission electron microscope (STEM) apparatus.

FIG. 10A shows a cross-sectional observation image of the sample 1 and FIG. 10B shows a cross-sectional observation image of the sample 2. In the oxide semiconductor films, the tungsten films, and interfaces therebetween, no difference was observed depending on whether bake treatment was performed.

Thus, it was confirmed that metal oxide was not likely to be formed at the interface between the tungsten film and the oxide semiconductor film, even when bake treatment was performed.

This example indicates that since tungsten does not easily react with oxygen, the use of a tungsten film for an electrode in contact with an oxide semiconductor layer can prevent the electrode from taking oxygen away from the oxide semiconductor layer.

### Example 2

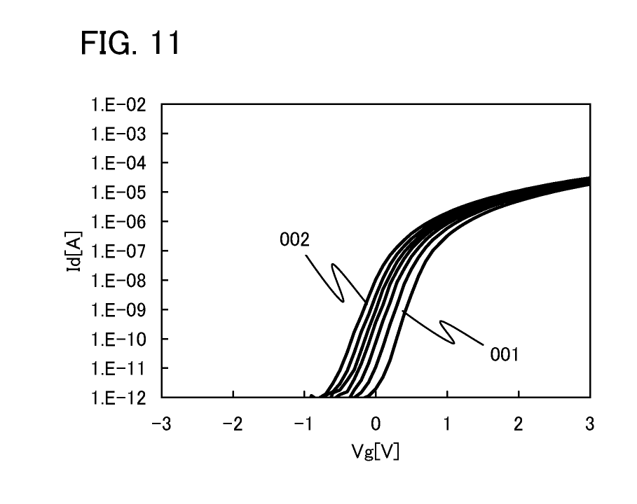

In this example, results of manufacturing a transistor in which tungsten is used for source and drain electrodes and comparing the transistor characteristics before and after a light bias test will be described with reference to FIG. 11.

First, a manufacturing method of the transistor used in this example will be described below.

First, a 100-nm-thick silicon nitride film and a 150-nm-thick silicon oxynitride film were formed successively by a plasma CVD method over a glass substrate to form a base film, and then a 100-nm-thick tungsten film was formed as a gate electrode over the silicon oxynitride film by a sputtering method. The tungsten film was etched selectively, thereby forming the gate electrode.

Then, a 30-nm-thick silicon oxynitride film was formed as a gate insulating film over the gate electrode by a plasma CVD method.

Next, a 15-nm-thick oxide semiconductor film was formed over the gate insulating film by a sputtering method using an In—Ga—Zn—O-based metal oxide target (In₂O₃:Ga₂O₃:ZnO=1:1:1 [molar ratio]) under a mixed atmosphere of argon and oxygen (argon:oxygen=50 sccm:50 sccm) at 200° C. under the following conditions: the distance between the substrate and the target was 80 mm, the pressure was 0.6 Pa, and the direct current (DC) power was 5 kW. Here, an island-shaped oxide semiconductor layer was formed by selectively etching the oxide semiconductor film.

Then, heat treatment was performed at 650° C. for six minutes in a nitrogen atmosphere by a rapid thermal annealing (RTA) method, and then heat treatment was performed at 450° C. for one hour in an atmosphere containing nitrogen and oxygen with the use of an oven.

Next, a tungsten film (with a thickness of 200 nm) was formed over the oxide semiconductor layer by a sputtering method at 230° C., as source and drain electrodes. Here, the tungsten film was selectively etched, so that a channel length L of the transistor was 3 μm and a channel width W thereof was 50 μm.

Next, heat treatment was performed at 300° C. for one hour in a nitrogen atmosphere with the use of an oven, and then a 300-nm-thick silicon oxide film was formed as a first interlayer insulating layer by a sputtering method. After that, the first interlayer insulating layer was selectively etched to expose an electrode to be used for measurement.

Then, a photosensitive acrylic resin was applied and subjected to light exposure and development treatment, and then heat treatment was performed at 250° C. for one hour in a nitrogen atmosphere with the use of an oven, so that a 1.5-μm-thick second interlayer insulating layer was formed.

Then, a 110-nm-thick indium tin oxide (ITO) film was formed by a sputtering method and was selectively etched, so that a pixel electrode was formed.

After that, baking was performed at 250° C. for one hour in a nitrogen atmosphere with the use of an oven.

Through the above process, the transistor having the channel length L of 3 μm and the channel width W of 50 μm was manufactured over the glass substrate.

Next, measurement results of the electric characteristics of the transistor of this example before and after the light bias test will be described. For the light bias test, a xenon light source having a spectrum with a peak at a wave length of 400 nm and a half width of 10 nm was used as a light source.

First, Id-Vg measurement of the transistor manufactured above was performed in a dark condition. In this example, the substrate temperature was 25° C. and the voltage between the source electrode and the drain electrode was 3 V.

Next, light irradiation was performed using the xenon light source with an irradiance of 326 μW/cm² and a voltage of 3 V was applied between the source electrode and the drain electrode to perform Id-Vg measurement. After that, the voltage of the source electrode was set to 0 V and the voltage of the drain electrode was set to 0.1 V in the transistor. Then, negative voltage was kept being applied to the gate electrode during a predetermined period so that the intensity of an electric field applied to the gate insulating layer was 2 MV/cm. After the predetermined period, the voltage of the gate electrode was set to 0 V. Then, the voltage between the source electrode and the drain electrode was set to 3 V, and Id-Vg measurement of the transistor was performed.

In the above manner, Id-Vg measurement of the transistor was performed every predetermined period. FIG. 11 shows results of the Id-Vg measurement of the transistor before and after the light bias test, obtained right after light irradiation and after 100 seconds, 300 seconds, 600 seconds, 1000 seconds, 1800 seconds, and 3600 seconds of the light irradiation.

In FIG. 11, a thin line 001 denotes a result of the Id-Vg measurement of the transistor obtained before the light bias test (right after light irradiation), and a thin line 002 denotes a result of the Id-Vg measurement of the transistor obtained after the light bias test for 3600 seconds. The threshold voltage obtained after the light bias test performed for 3600 seconds shifted by about 0.55 V in the negative direction as compared with the threshold voltage obtained before the light bias test.

From these results, it was confirmed that the transistor of this embodiment in which tungsten was used for the source and drain electrodes had small variation in threshold voltage between before and after the light bias test.

### Example 3

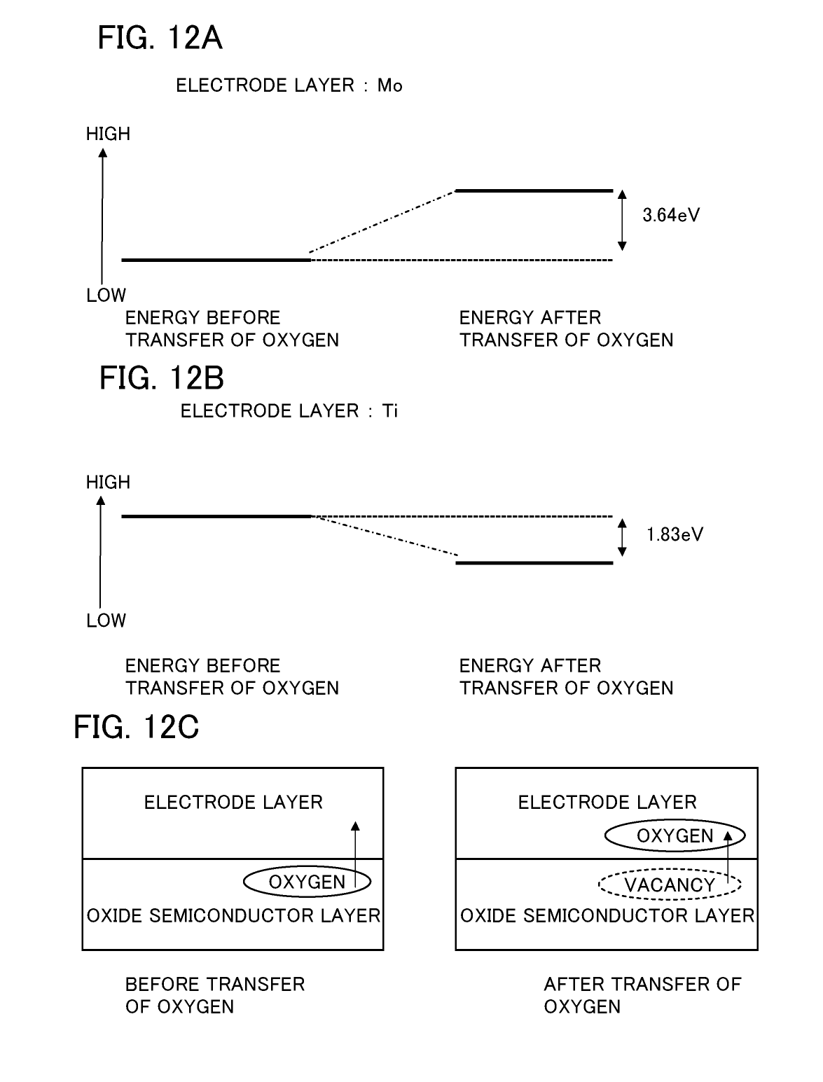

In this example, results of calculating, in a stacked-layer structure of an oxide semiconductor layer and an electrode (source electrode or drain electrode) shown in FIG. 12C, an energy change between before and after transfer of oxygen from the oxide semiconductor layer to the electrode will be described.

Specifically, in the stacked-layer structure, an energy change between before and after an oxygen vacancy was generated in the oxide semiconductor layer and oxygen was inserted between lattices in the electrode was calculated. By comparison of the energy before and after oxygen was extracted from the oxide semiconductor layer to be inserted between lattices in the electrode, the stability after oxygen has transferred was evaluated.

As a material of the oxide semiconductor layer, an In—Ga—Zn—O-based oxide semiconductor (hereinafter referred to as IGZO) was used. As a material of the electrode, titanium (Ti), molybdenum (Mo), tungsten (W), and platinum (Pt) were used.

The calculation was performed on bulk structures of “an IGZO crystal”, “an IGZO crystal with one oxygen vacancy”, “a crystal of the electrode”, and “a crystal of the electrode in which oxygen was inserted between lattices”. Therefore, effects of interfaces will not be considered in the calculation of this example. For the calculation, each of W, Mo, Pt, and Ti was used for the electrode.

The calculation was performed using first-principles calculation software, “CASTEP”. A plan wave basis pseudopotential method was used as a method for the density functional theory, and GGA-PBE was used for a functional. The cut-off energy was 500 eV. The k-point set for IGZO; W, Mo, and Pt; and Ti were grids of 3×3×1, 3×3×3, and 2×2×3, respectively.

Definitions of the calculated values are shown below.

ΔE=(the energy after transfer of oxygen)−(the energy before transfer of oxygen)=E(an IGZO crystal with one oxygen vacancy)+E(a crystal of the electrode in which oxygen was inserted between lattices)−{E(an IGZO crystal)+E(a crystal of the electrode)}

ΔE represents an energy change in transfer of oxygen from the IGZO into a space between lattices in the electrode. When ΔE is a positive value, it is considered that oxygen does not easily transfer because the energy after transfer is higher. When ΔE is a negative value, it is considered that oxygen easily transfers because the energy after transfer is lower. Note that the energy with which oxygen goes over a barrier, needed for transfer of oxygen is not considered in this example.

The defect formation energy of oxygen in the IGZO varies depending on which metal is bonded to oxygen. In this example, calculation was performed using the defect formation energy in the case where oxygen was most easily extracted from the IGZO crystal as a reference. Similarly, the energy of the whole system varies depending on the position of oxygen inserted between lattices in the electrode. In this example, the case where the oxygen between lattices made the energy of the whole system the lowest was considered.

A crystal structure of the IGZO crystal was a structure of 84 atoms which was obtained by doubling a structure among the inorganic crystal structure database (ICSD, collection number: 90003) in both a-axis and b-axis directions, and by arranging Ga and Zn such that the energy becomes a minimum. A crystal structure of each of an Mo crystal and a W crystal was a body-centered cubic lattice structure (space group: Im-3m, international number: 229) of 54 atoms, a crystal structure of a Pt crystal was a face-centered cubic lattice structure (space group: Fm-3m, international number: 225) of 32 atoms, and a crystal structure of a Ti crystal was a hexagonal crystal structure (space group: P63/mmc) of 64 atoms.

The calculation results are shown in Table 1. Table 1 shows an energy change in transfer of oxygen at an interface between the IGZO and the electrode.

TABLE 1

| Electrode | Energy change in oxygen transfer (eV) |
|---|---|
| Ti | −1.83 |
| Mo | 3.64 |
| W | 4.29 |
| Pt | 5.56 |

As shown in Table 1, the energy change was a positive value in the case where each of Mo, W, and Pt was used for the electrode (FIG. 12A shows an example where Mo was used for the electrode). Thus, it was found that since the energy was higher after transfer of oxygen, oxygen did not easily transfer and therefore an oxide film (for example, a molybdenum oxide film or the like) was not likely to be formed between the oxide semiconductor layer and the electrode. On the other hand, as shown in Table 1 and FIG. 12B, the energy change was a negative value in the case where Ti was used for the electrode. Thus, it was found that since the energy was lower after transfer of oxygen, oxygen easily transferred and therefore a titanium oxide film was likely to be formed.

The above results indicate that the use of Mo, W, or Pt for an electrode (source electrode or drain electrode) can prevent the electrode from taking oxygen away from an oxide semiconductor layer.

### Example 4

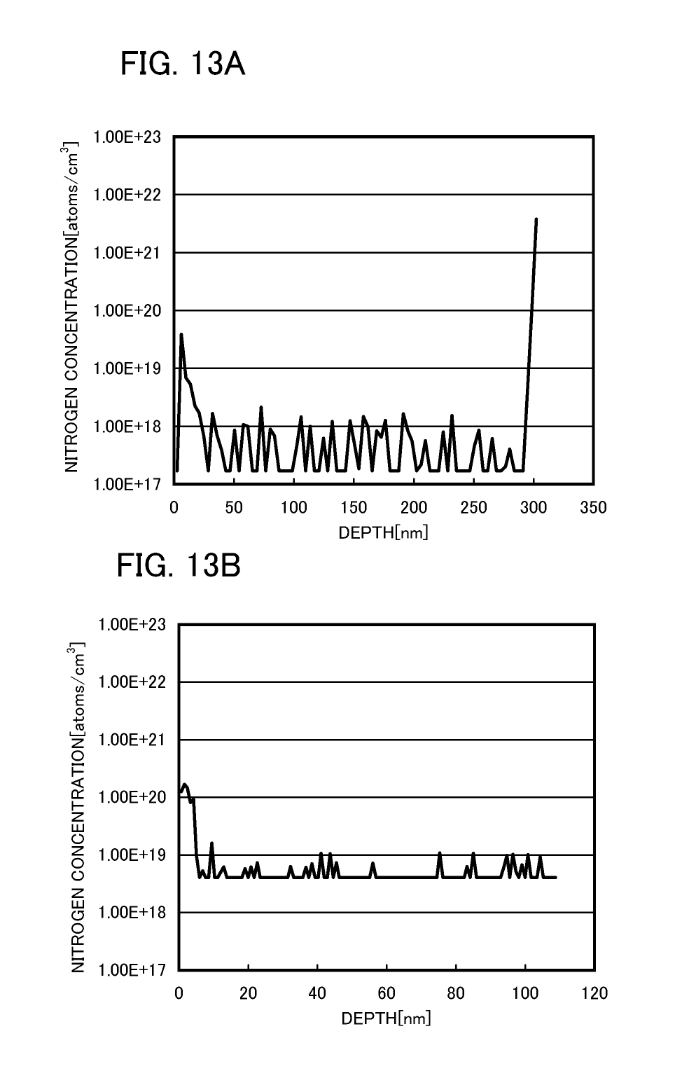

In this example, results of SIMS analysis of an oxide semiconductor film which can be applied to one embodiment of the present invention will be described with reference to FIGS. 13A and 13B.

First, a method for manufacturing samples A and B of this example is described.

### (Sample A)

A 300-nm-thick oxide semiconductor film was formed over a glass substrate by a sputtering method using an In—Ga—Zn—O-based metal oxide target (In:Ga:Zn=1:1:1 [atomic ratio]) under an oxygen atmosphere (the flow rate of oxygen is 40 sccm) at a substrate temperature of 200° C. under the following conditions: the distance between the substrate and the target was 60 mm, the pressure was 0.4 Pa, and the direct current (DC) power was 0.5 kW.

### (Sample B)

A 100-nm-thick oxide semiconductor film was formed over a glass substrate by a sputtering method using an In—Ga—Zn—O-based metal oxide target (In:Ga:Zn=1:1:1 [atomic ratio]) under a mixed atmosphere of argon and oxygen (argon:oxygen=30 sccm:15 sccm) at a substrate temperature of 200° C. under the following conditions: the distance between the substrate and the target was 60 mm, the pressure was 0.4 Pa, and the direct current (DC) power was 0.5 kW.

SIMS analysis results of the nitrogen concentrations in the oxide semiconductor films in the samples A and B are shown in FIGS. 13A and 13B, respectively. A horizontal axis indicates a depth from surfaces of the samples, and a left end where the depth is 0 nm corresponds to the outermost surfaces of the samples (outermost surfaces of the oxide semiconductor films), and analysis is performed from the surface side.

It is known that it is difficult to obtain accurate data in the proximity of a surface of a sample by the SIMS in principle. In this analysis, data obtained at depths of greater than or equal to 50 nm were evaluated in order to obtain accurate data on the inside of the film.

FIG. 13A shows a nitrogen concentration profile of the sample A. FIG. 13B shows a nitrogen concentration profile of the sample B. In both of the samples A and B, the nitrogen concentration in the film was 2×10¹⁹ atoms/cm³ or lower. In many regions, the concentrations reached the measurement limit, where the actual concentrations seem to be further lower.

The results of this example indicate that the nitrogen concentration in an oxide semiconductor film formed in an oxygen atmosphere is low. In addition, the results of this example indicate that the nitrogen concentration in an oxide semiconductor film formed in a mixed atmosphere of argon and oxygen is low. Specifically, it was found that the nitrogen concentration was 2×10¹⁹ atoms/cm³ or lower.

This application is based on Japanese Patent Application serial no. 2010-152179 filed with Japan Patent Office on Jul. 2, 2010 and Japanese Patent Application serial no. 2011-100534 filed with Japan Patent Office on Apr. 28, 2011, the entire contents of which are hereby incorporated by reference.

What is claimed is:

1. A semiconductor device comprising:
a gate insulating layer;
a first gate electrode in contact with one surface of the gate insulating layer;
an oxide semiconductor layer in contact with the other surface of the gate insulating layer and overlapping with the first gate electrode; and
a source electrode, a drain electrode, and an oxide insulating layer which are in contact with the oxide semiconductor layer,
wherein a nitrogen concentration of the oxide semiconductor layer is 2×10¹⁹ atoms/cm³ or lower, and
wherein the source electrode and the drain electrode include at least one of tungsten, platinum, and molybdenum.

2. The semiconductor device according to claim 1, wherein the gate insulating layer includes at least one of gallium oxide, aluminum oxide, gallium aluminum oxide, and aluminum gallium oxide.

3. The semiconductor device according to claim 1, wherein the oxide insulating layer includes at least one of gallium oxide, aluminum oxide, gallium aluminum oxide, and aluminum gallium oxide.

4. The semiconductor device according to claim 1, wherein a thickness of the oxide semiconductor layer is greater than or equal to 3 nm and less than or equal to 30 nm.

5. The semiconductor device according to claim 1, further comprising a second gate electrode overlapping with the oxide semiconductor layer and the first gate electrode with the oxide insulating layer interposed therebetween.

6. The semiconductor device according to claim 1, wherein the oxide insulating layer contains a Group 13 element.

7. The semiconductor device according to claim 1, wherein the oxide insulating layer includes a region containing oxygen with a higher composition proportion than a stoichiometric composition proportion.

8. The semiconductor device according to claim 1, wherein the gate insulating layer includes a region containing oxygen with a higher composition proportion than a stoichiometric composition proportion.

9. The semiconductor device according to claim 1, wherein nitrogen concentrations of the source electrode and the drain electrode are 2×10¹⁹ atoms/cm³ or lower.

10. The semiconductor device according to claim 1, wherein the oxide insulating layer comprises a metal oxide.

11. A semiconductor device comprising:
a gate insulating layer;
a first gate electrode in contact with one surface of the gate insulating layer;
an oxide semiconductor layer in contact with the other surface of the gate insulating layer and overlapping with the first gate electrode;
a buffer layer and an oxide insulating layer which are in contact with the oxide semiconductor layer; and
a source electrode and a drain electrode which are electrically connected to the oxide semiconductor layer with the buffer layer interposed therebetween,
wherein a nitrogen concentration of the oxide semiconductor layer is 2×10¹⁹ atoms/cm³ or lower,
wherein a nitrogen concentration of the buffer layer is 2×10¹⁹ atoms/cm³ or lower, and
wherein the source electrode and the drain electrode include at least one of tungsten, platinum, and molybdenum.

12. The semiconductor device according to claim 11, wherein the gate insulating layer includes at least one of gallium oxide, aluminum oxide, gallium aluminum oxide, and aluminum gallium oxide.

13. The semiconductor device according to claim 11, wherein the oxide insulating layer includes at least one of gallium oxide, aluminum oxide, gallium aluminum oxide, and aluminum gallium oxide.

14. The semiconductor device according to claim 11, wherein a thickness of the oxide semiconductor layer is greater than or equal to 3 nm and less than or equal to 30 nm.

15. The semiconductor device according to claim 11, further comprising a second gate electrode overlapping with the oxide semiconductor layer and the first gate electrode with the oxide insulating layer interposed therebetween.

16. The semiconductor device according to claim 11, wherein the oxide insulating layer contains a Group 13 element.

17. The semiconductor device according to claim 11, wherein the oxide insulating layer includes a region containing oxygen with a higher composition proportion than a stoichiometric composition proportion.

18. The semiconductor device according to claim 11, wherein the gate insulating layer includes a region containing oxygen with a higher composition proportion than a stoichiometric composition proportion.

19. The semiconductor device according to claim 11, wherein nitrogen concentrations of the source electrode and the drain electrode are 2×10¹⁹ atoms/cm³ or lower.

20. The semiconductor device according to claim 11, wherein the oxide insulating layer comprises a metal oxide.
